(19) United States
(12) Patent Application Publication
(10) Pub. No.: US 2025/0279038 A1
(43) Pub. Date: Sep. 4, 2025

(54) Display Device

(71) Applicant: LG Display Co., Ltd., Seoul (KR)

(72) Inventors: JaeHee Park, Paju-si (KR); Jongsung Kim, Paju-si (KR); Hoiyong Kwon, Paju-si (KR); Sunghee Park, Paju-si (KR)

(21) Appl. No.: 18/965,944

(22) Filed: Dec. 2, 2024

(30) Foreign Application Priority Data
Feb. 29, 2024 (KR) 10-2024-0030019

(51) Int. Cl. G09G 3/32; G09G 3/00

(52) U.S. Cl. CPC G09G 3/32; G09G 3/006; G09G 2300/0426; G09G 2330/12

(57) ABSTRACT

A display device and manufacturing method thereof is provided. the display device comprises a driving transistor provided on a substrate, a light emitting element provided on the driving transistor, including an anode electrode, a light emitting layer, and a cathode electrode, the anode electrode including a first anode electrode and a second anode electrode, which are disposed to be spaced apart from each other, a first anode connection line electrically connecting the first anode electrode to the driving transistor, and a second anode connection line electrically connecting the second anode electrode to the driving transistor. The first anode connection line has resistance greater than that of the second anode connection line.

### CROSS-REFERENCE TO RELATED APPLICATION

This application claims the benefit of the Republic of Korea Patent Application No. 10-2024-0030019 filed on Feb. 29, 2024, which is hereby incorporated by reference in its entirety.

### BACKGROUND

### Field of Technology

The present disclosure relates to a display device and a manufacturing method thereof, and more particularly, for example, without limitation, to a display device that may minimize a size of a light emission area that becomes a dark spot and a manufacturing method thereof.

### Description of the Related Art

A display device may include a first electrode, a light emitting layer, and a second electrode, which are sequentially deposited, and may emit light through the light emitting layer when a voltage is applied to the first electrode and the second electrode.

The description provided in the description of the related art section should not be assumed to be prior art merely because it is mentioned in or associated with the description of the related art section. The description of the related art section may include information that describes one or more aspects of the subject technology, and the description in this section does not limit the invention.

### SUMMARY

The inventors have recognized that, in this display device, particles may occur on the first electrode during a manufacturing process, and in this case, a short may occur between the first electrode and the second electrode in the area in which the particles occur. For this reason, the display device has a problem in that all of subpixels in which particles occur become dark spots so as not to emit light. As a result, luminance of the display device may be deteriorated.

Accordingly, the present disclosure has been made in view of the above problems and it is an object of the present disclosure to provide a display device that may minimize a size of a light emission area that becomes a dark spot.

It is another object of the present disclosure to provide a display device that may certainly become a dark spot in only an area in which particles occur.

It is other object of the present disclosure to provide a display device that may implement environment/social/governance (ESG) by reducing occurrence of greenhouse gas, which may occur due to a manufacturing process.

In addition to the objects of the present disclosure as mentioned above, additional objects and features of the present disclosure will be clearly understood by those skilled in the art from the following description of the present disclosure.

In accordance with an aspect of the present disclosure, the above and other objects may be accomplished by the provision of a display device comprising a driving transistor provided on a substrate, a light emitting element provided on the driving transistor, including an anode electrode, a light emitting layer, and a cathode electrode, the anode electrode including a first anode electrode and a second anode electrode, which are disposed to be spaced apart from each other, a first anode connection line electrically connecting the first anode electrode to the driving transistor, and a second anode connection line electrically connecting the second anode electrode to the driving transistor. The first anode connection line has resistance greater than that of the second anode connection line.

In accordance with another aspect of the present disclosure, the above and other objects may be accomplished by the provision of a display device comprising a substrate provided with a plurality of transmissive areas and a plurality of subpixels disposed between the plurality of transmissive areas, a driving transistor provided on the substrate, including an active layer, a gate electrode, a source electrode and a drain electrode, an anode electrode provided in each of the plurality of subpixels, including a first anode electrode and a second anode electrode, a first anode connection line electrically connecting the first anode electrode to the driving transistor, and a second anode connection line electrically connecting the second anode electrode to the driving transistor. The first anode connection line is provided on the same layer as the active layer of the driving transistor.

In accordance with another aspect of the present disclosure, the above and other objects may be accomplished by the provision of a manufacturing method of a display device comprising: forming a driving transistor on a substrate; providing a light emitting element over the driving transistor, the driving transistor including an anode electrode, a light emitting layer, and a cathode electrode, the anode electrode including a first anode electrode and a second anode electrode, which are disposed to be spaced apart from each other; providing a first anode connection line electrically connecting the first anode electrode to the driving transistor; and providing a second anode connection line electrically connecting the second anode electrode to the driving transistor, wherein the first anode connection line has resistance greater than that of the second anode connection line.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory, and are intended to provide further explanation of the inventive concepts as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic perspective view illustrating a display device according to one exemplary embodiment of the present disclosure;

FIG. 2 is a schematic plan view illustrating a display panel according to one exemplary embodiment of the present disclosure;

FIG. 3 is a schematic view illustrating one exemplary embodiment of a pixel provided in an area A of FIG. 2;

FIG. 4 is a circuit view illustrating an example of a circuit element of a subpixel shown in FIG. 3;

FIG. 5 is a plan view illustrating an example of first and second light emitting elements connected to one circuit element;

FIG. 6 is a cross-sectional view illustrating an example of I-I′ of FIG. 5;

FIG. 7 is a cross-sectional view illustrating an example of II-II′ of FIG. 5;

FIG. 8 is a cross-sectional view illustrating another example of I-I′ of FIG. 5;

FIG. 9 is a schematic view illustrating another exemplary embodiment of a pixel provided in an area A of FIG. 2;

FIG. 10 is a plan view illustrating an example of first and second light emitting elements connected to one circuit element in FIG. 9;

FIG. 11 is a view illustrating an example of driving waveforms in a defect inspection mode;

FIG. 12 is a view illustrating an operation of a subpixel for an initial period;

FIG. 13 is a view illustrating an example in which a defect occurs in a first light emitting element;

FIG. 14 is a view illustrating an operation of a subpixel for a discharge period when a defect occurs in a first light emitting element;

FIG. 15 is a view illustrating an example in which a defect occurs in a second light emitting element;

FIG. 16 is a view illustrating an operation of a subpixel for a discharge period when a defect occurs in a second light emitting element; and

FIG. 17 is a graph illustrating a change of a sensing voltage when a defect occurs in a first light emitting element and when a defect occurs in a second light emitting element.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following exemplary embodiments described with reference to the accompanying drawings. The present disclosure may, however, be embodied in different forms and should not be construed as limited to the exemplary embodiments set forth herein. Rather, these exemplary embodiments are provided so that this disclosure will be thorough and complete and will fully convey the scope of the present disclosure to those skilled in the art.

A shape, a size, a ratio, an angle and a number disclosed in the drawings for describing exemplary embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where “include,” “have,” “comprise,” “contain,” “constitute,” “make up of,” “formed of,” and “consist of” described in the present disclosure are used, another portion may be added unless ‘only˜’ is used. The terms of a singular form may include plural forms unless referred to the contrary.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In construing an element, the element is construed as including an error band although there is no explicit description.

In describing a position relationship, for example, when the position relationship is described as “on”, “above”, “over”, “below”, “under”, “beside”, “beneath”, “near”, “close to,” “adjacent to”, “on a side of”, “next”, one or more portions may be disposed between two other portions unless ‘just’ or ‘direct’ is used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When an element or layer is disposed “on” another element or layer, another layer or another element may be interposed directly on the other element or therebetween.

In describing a temporal relationship, for example, when the temporal order is described as “after,” “subsequent,” “next,” and “before,” a case which is not continuous may be included, unless “just” or “direct” is used.

It will be understood that, although the terms “first”, “second”, “A”, “B”, “(A)”, or “(B)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

It should be understood that the term “at least one” includes all combinations related with any one item. For example, “at least one among a first element, a second element and a third element” may include all combinations of two or more elements selected from the first, second and third elements as well as each element of the first, second and third elements.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Features of various exemplary embodiments of the present disclosure may be partially or overall coupled to or combined with each other, and may be variously inter-operated with each other and driven technically as those skilled in the art can sufficiently understand. The exemplary embodiments of the present disclosure may be carried out independently from each other, or may be carried out together in a co-dependent relationship.

Hereinafter, an exemplary embodiment of a display device according to the present disclosure will be described in detail with reference to the accompanying drawings. Wherever possible, the same reference numbers will be used throughout the drawings to refer to the same or like parts. Also, in the following description, when the detailed description of the relevant known art is determined to unnecessarily obscure the subject matter of the present disclosure, the detailed description will be omitted.

Hereinafter, the exemplary embodiment of the present disclosure will be described in detail with reference to the accompanying drawings.

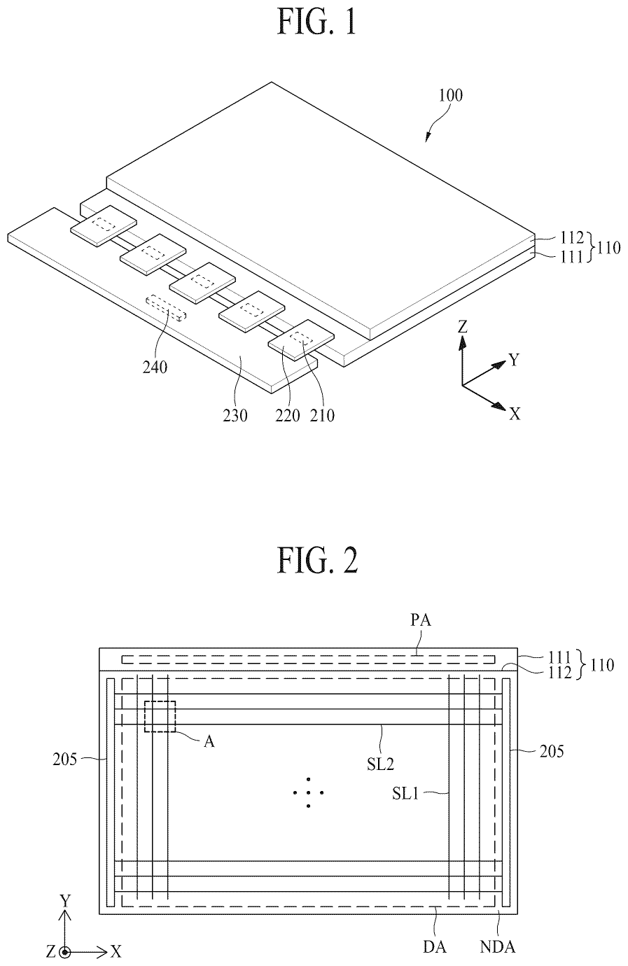

FIG. 1 is a schematic perspective view illustrating a display device according to one exemplary embodiment of the present disclosure. FIG. 2 is a schematic plan view illustrating a display panel according to one exemplary embodiment of the present disclosure.

Hereinafter, X-axis represents a direction parallel with a gate line, Y-axis represents a direction parallel with a data line, and Z-axis represents a height direction of a display device 100. However, the present disclosure is not limited thereto, for example, Y-axis may represent a direction parallel with a gate line, X-axis may represent a direction parallel with a data line, and Z-axis may represent a height direction of a display device 100.

Although the display device 100 according to one exemplary embodiment of the present disclosure will be described to be implemented as an organic light emitting display (OLED), it may be also implemented as a liquid crystal display (LCD), a plasma display panel (PDP), a quantum dot light emitting display (QLED), or an electrophoresis display.

Referring to FIGS. 1 and 2, the display device 100 according to one exemplary embodiment of the present disclosure may include a display panel 110, a source drive integrated circuit (hereinafter, referred to as “IC”) 210, a flexible film 220, a circuit board 230, and a timing controller 240.

The display panel 110 includes a first substrate 111 and a second substrate 112, which face each other. The second substrate 112 may be an encapsulation substrate. The first substrate 111 may be a plastic film, a glass substrate or a silicon wafer substrate formed using a semiconductor process. The second substrate 112 may be a plastic film, a glass substrate or an encapsulation film. The first substrate 111 and the second substrate 112 may be made of a transparent material.

The display panel 110 may be categorized into a display area DA in which pixels P are formed to display an image, and a non-display area NDA for not displaying an image. The non-display area NDA may be an area adjacent to the display area DA. Further, the non-display area NDA may be an area disposed adjacent to the display area DA and configured to surround the display area DA. However, the present disclosure is not limited thereto.

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction.

For another example, a boundary area between the display area DA and the non-display area NDA may be bent so that the non-display area NDA may be located below the display area. In this case, when the user looks at the display device from the front, there may be little or no non-display area NDA visible to the user.

First signal lines SL1, second signal lines SL2 and pixels P may be provided in the display area DA, and a pad area PA in which pads are disposed and at least one scan driver 205 may be provided in the non-display area NDA.

The first signal lines SL1 may be extended in a second direction (e.g., Y-axis direction), and may cross the second signal lines SL2 in the display area DA. The second signal lines SL2 may be extended in a first direction (or X-axis direction). The pixels are disposed in an area where the first signal line SL1 is provided, an area in which the second signal line SL2 is provided, or an area where the first signal line SL1 and the second signal line SL2 cross each other, and emit predetermined light to display an image.

A plurality of pads may be disposed in the pad area PA. Since a size of the first substrate 111 is greater than that of the second substrate 112, a portion of the first substrate 111 may be exposed without being covered by the second substrate 112. Pads such as power pads and data pads may be provided in a portion of the first substrate 111, which is exposed without being covered by the second substrate 112.

The scan driver 205 may be connected to scan lines to supply scan signals. The scan driver 205 may be formed in the non-display area NDA outside one side or both sides of the display area DA of the display panel 110 in a gate driver in panel (GIP) mode. Alternatively, the scan driver 205 may be manufactured as a driving chip, packaged on the flexible film and attached to the non-display area NDA outside one side or both sides of the display area DA of the display panel 110 in a tape automated bonding (TAB) mode.

The source drive IC 210 receives digital video data and a data control signal from the timing controller 240. The source drive IC 210 converts digital video data into analog data voltages in accordance with a data control signal and supplies the analog data voltages to data lines. When the source drive IC 210 is manufactured as a driving chip, the source drive IC 210 may be packaged on the flexible film 220 by a chip on film (COF) mode or a chip on plastic (COP) mode.

Lines for connecting the pads to the source drive IC 210 and lines for connecting the pads to lines of the circuit board 230 may be formed in the flexible film 220. The flexible film 220 is attached onto the pads by using an anisotropic conducting film, so that the pads and the lines of the flexible film 220 may be connected to each other.

The circuit board 230 may be attached to the flexible films 220. A plurality of circuits implemented with driving chips may be packaged on the circuit board 230. For example, the timing controller 240 may be packaged on the circuit board 230. The circuit board 230 may be a printed circuit board or a flexible printed circuit board.

The timing controller 240 receives digital video data and a timing signal from an external system board (not shown). The timing controller 240 generates a scan control signal for controlling the operation timing of the scan driver and a data control signal for controlling the source drive ICs 210 based on the timing signal. The timing controller 240 supplies the scan control signal to the scan driver 205, and supplies the data control signal to the source drive ICs 210.

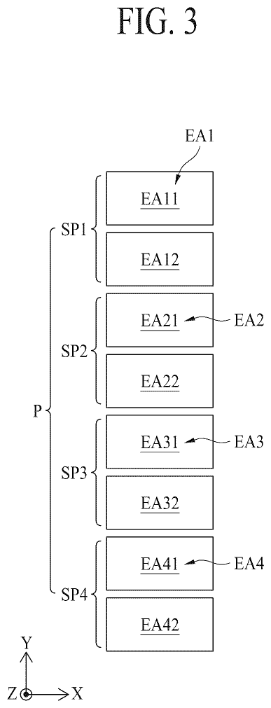

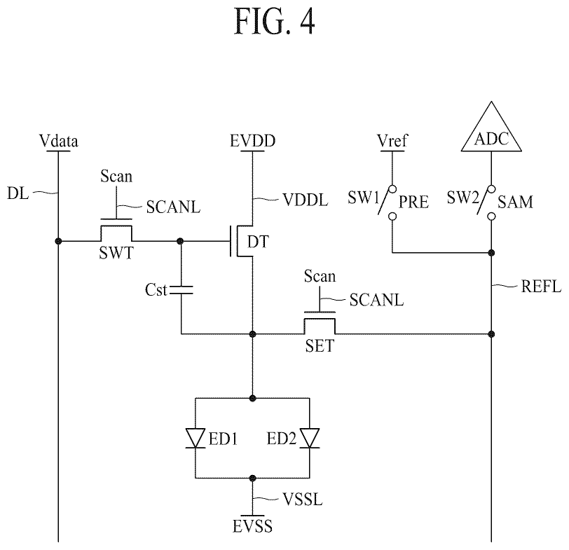

FIG. 3 is a schematic view illustrating one exemplary embodiment of a pixel provided in an area A of FIG. 2, and FIG. 4 is a circuit view illustrating an example of a circuit element of a subpixel shown in FIG. 3.

The display panel 110 according to one exemplary embodiment of the present disclosure may be categorized into a display area DA in which pixels P are formed to display an image, and a non-display area NDA (FIG. 2) for not displaying an image.

Each of the plurality of subpixels SP is a minimum unit which configures the display area and n subpixels SP form one pixel. Each of the plurality of subpixels SP may emit light having different wavelengths from each other. The plurality of subpixels may include first to third subpixels which emit different color light from each other. For example, the plurality of subpixels SP may include red subpixels SP, green subpixels SP, and blue subpixels SP. According to the exemplary embodiment, at least some of the plurality of pixels may further include white subpixels SP. The plurality of subpixels SP may be variously modified in colors and configurations, as necessary. However, the present disclosure is not limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

In detail, each of the pixels P includes a plurality of subpixels SP1, SP2, SP3 and SP4. The plurality of subpixels SP1, SP2, SP3 and SP4 may be provided in the form of a matrix, and may display an image by emitting predetermined light. The plurality of subpixels SP1, SP2, SP3 and SP4 may include a plurality of row lines comprising subpixels SP1, SP2, SP3 and SP4 arranged in the first direction (e.g., X-axis direction) and a plurality of column lines comprising subpixels SP1, SP2, SP3 and SP4 arranged in the second direction (e.g., Y-axis direction).

Each pixel P may include at least two subpixels. For example, each pixel P may include a first subpixel SP1, a second subpixel SP2 and a third subpixel SP3, but is not limited thereto. Each pixel P may further include a fourth subpixel SP4.

The first subpixel SP1 may include a first light emission area EA1 that emits light of a first color, and the second subpixel SP2 may include a second light emission area EA2 that emits light of a second color. The third subpixel SP3 may include a third light emission area EA3 that emits light of a third color, and the fourth subpixel SP4 may include a fourth light emission area EA4 that emits light of a fourth color.

The first to fourth light emission areas EA1, EA2, EA3 and EA4 may emit light of different colors. For example, the first light emission area EA1 may emit red light, and the second light emission area EA2 may emit green light. The third light emission area EA3 may emit blue light, and the fourth light emission area EA4 may emit white light. However, the present disclosure is not limited to the above example. Also, various modifications may be made in the arrangement order of the subpixels SP1, SP2, SP3 and SP4.

Meanwhile, the light emission areas EA1, EA2, EA3 and EA4 respectively provided in the plurality of subpixels SP1, SP3 and SP4 may include a plurality of light emission areas divided into a plural number. In detail, the first light emission area EA1 provided in the first subpixel SP1 may be divided into two and thus may include a first sub-light emission area EA11 and a second sub-light emission area EA12. The second light emission area EA2 provided in the second subpixel SP2 may be divided into two and thus may include a first sub-light emission area EA21 and a second sub-light emission area EA22. The third light emission area EA3 provided in the third subpixel SP3 may be divided into two and thus may include a first sub-light emission area EA31 and a second sub-light emission area EA32. The fourth light emission area EA4 provided in the fourth subpixel SP4 may be divided into two and thus may include a first sub-light emission area EA41 and a second sub-light emission area EA42.

Hereinafter, for convenience of description, each of emission areas EA1, EA2, EA3 and EA4 of the plurality of subpixels SP1, SP2, SP3 and SP4 includes two light emission areas respectively, but are not limited thereto. Each of emission areas EA1, EA2, EA3 and EA4 of the plurality of subpixels SP1, SP2, SP3 and SP4 may include more than two light emission areas.

In detail, the first light emission area EA1 provided in the first subpixel SP1 can include a first sub-light emission area EA11 and a second sub-light emission area EA12, which are divided into two. The second light emission area EA2 provided in the second subpixel SP2 can include a first sub-light emission area EA21 and a second sub-light emission area EA22, which are divided into two. The third light emission area EA3 provided in the third subpixel SP3 can include a first sub-light emission area EA31 and a second sub-light emission area EA32, which are divided into two. The fourth light emission area EA4 provided in the fourth subpixel SP4 can include a first sub-light emission area EA41 and a second sub-light emission area EA42, which are divided into two. However, the present disclosure is not limited thereto, the light emission areas EA1, EA2, EA3 and EA4 respectively provided in the plurality of subpixels SP1, SP3 and SP4 can include a plurality of light emission areas divided into more than two, for example, the first light emission area EA1 provided in the first subpixel SP1 can include a first sub-light emission area, a second sub-light emission area and a third sub-light emission area, which are divided into three. The second light emission area EA2 provided in the second subpixel SP2 can include a first sub-light emission area, a second sub-light emission area and a third sub-light emission area, which are divided into three. The third light emission area EA3 provided in the third subpixel SP3 can include a first sub-light emission area, a second sub-light emission area and a third sub-light emission area, which are divided into three. The fourth light emission area EA4 provided in the fourth subpixel SP4 can include a first sub-light emission area, a second sub-light emission area and a third sub-light emission area, which are divided into three.

Each of the plurality of subpixels SP1, SP2, SP3 and SP4 may include a light emitting element for emitting light and a circuit element. In detail, each of the plurality of subpixels SP1, SP2, SP3 and SP4 may include a circuit element having a 3T (Transistor) 1C (capacitor) structure that includes a switching transistor SWT, a sensing transistor SET, a driving transistor DT and a capacitor Cst, and first and second light emitting elements ED1 and ED2, but is not limited thereto. Each of the subpixels SP1, SP2, SP3 and SP4 may further include a compensation circuit, and in this case, may have various structures such as 4T2C, 5T2C, 6T1C, 6T2C, 7T1C and 7T2C.

The transistors may be thin-film transistors TFTs. Active layers of thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Each of the transistors DT, SWT and SET of each of the subpixels SP1, SP2, SP3 and SP4 may include a gate electrode, a source electrode, and a drain electrode. Since the source electrode and the drain electrode are not fixed and may be changed in accordance with a voltage and a current direction, which are applied to the gate electrode, one of the source electrode and the drain electrode may be expressed as a first electrode, and the other one may be expressed as a second electrode. The transistors DT, SWT and SET of each of the subpixels SP1, SP2, SP3 and SP4 may use at least one of a polysilicon semiconductor, an amorphous silicon semiconductor, or an oxide semiconductor. The transistors DT, SWT and SET may be P-type or N-type transistors, or P-type and N-type transistors may be used interchangeably.

The switching transistor SWT may charge the capacitor Cst with a data voltage Vdata supplied from a data line DL. The gate electrode of the switching transistor SWT may be connected to a scan line SCANL, and the first electrode thereof may be connected to the data line DL. Also, the second electrode of the first switching transistor SWT may be connected to one end of the capacitor Cst and the gate electrode of the driving transistor DT.

The switching transistor SWT may be turned on in response to a scan signal Scan applied through the scan line SCANL. When the switching transistor SWT is turned on, the data voltage Vdata applied through the data line DL may be transferred to one end of the capacitor Cst.

The sensing transistor SET may serve to supply a reference voltage Vref supplied from a reference line REFL to the driving transistor DT. In detail, the gate electrode of the sensing transistor SET may be connected to the scan line SCANL, and the first electrode thereof may be connected to the reference line REFL. Also, the second electrode of the sensing transistor SET may be connected to the first electrode of the driving transistor DT and the other end of the capacitor Cst.

Meanwhile, the reference line REFL may be connected to a reference voltage source VREF or an analog-digital (AD) converter ADC in accordance with the control signal. A first switch SW1 may connect or disconnect the reference voltage source VREF to or from the reference line REFL in accordance with an initialization control signal PRE. When the first switch SW1 is turned on in accordance with the initialization control signal PRE of a turn-on level, the reference line REFL may be initialized to the reference voltage Vref by being connected to the reference voltage source VREF. Also, when the first switch SW1 is turned off in accordance with the initialization control signal PRE of a turn-off level, the reference line REFL may be disconnected from the reference voltage source VREF.

A second switch SW2 may connect or disconnect the AD converter ADC to or from the reference line REFL in accordance with a sampling control signal SAM. When the second switch SW2 is turned on in accordance with the sampling control signal SAM of a turn-on level, the reference line REFL may be connected to the AD converter ADC. The AD converter ADC may sense a voltage charged in the reference line REFL. Also, when the second switch SW2 is turned off in accordance with the sampling control signal SAM of the turn-off level, the reference line REFL may be disconnected from the AD converter ADC.

The sensing transistor SET may be turned on in response to the scan signal Scan applied through the scan line SCANL. When the sensing transistor SET is turned on, the reference voltage Vref (or the initialization voltage) applied through the reference line REFL may be transferred to the other end of the capacitor Cst. Also, the reference voltage Vref may be applied to the source electrode of the driving transistor DT.

The capacitor Cst may serve to maintain the data voltage Vdata supplied to the driving transistor DT during one frame. In detail, the first electrode of the capacitor Cst may be connected to the gate electrode of the driving transistor DT, and the second electrode thereof may be connected to the source electrode of the driving transistor DT. The capacitor Cst may charge a driving voltage Vgs corresponding to the data voltage Vdata transferred through the switching transistor SWT and supply the charged driving voltage Vgs to the driving transistor DT.

The driving transistor DT may serve to generate a driving current Ids from a first power source EVDD supplied from a pixel power source line VDDL and supply the driving current Ids to an anode electrode of the first light emitting element ED1 and an anode electrode of the second light emitting element ED2. The gate electrode of the driving transistor DT may be connected to one end of the capacitor Cst, and the first electrode thereof may be connected to the pixel power source line VDDL. Also, the second electrode of the driving transistor DT may be connected to the anode electrode of the first light emitting element ED1 and the anode electrode of the second light emitting element ED2.

The driving transistor DT may be turned on in accordance with the driving voltage Vgs charged in the capacitor Cst. When the driving transistor DT is turned on, the first power source EVDD applied through the pixel power line VDDL may be transferred to the anode electrode of the first light emitting element ED1 and the anode electrode of the second light emitting element ED2. The driving transistor DT may control light emission intensity of the first and second light emitting elements ED1 and ED2 by controlling the driving current Ids in accordance with the driving voltage Vgs charged in the capacitor Cst.

The first and second light emitting elements ED1 and ED2 may include an anode electrode connected to the driving transistor DT, a cathode electrode receiving a second power source EVSS from a common power line VSSL, and a light emitting layer between the anode electrode and the cathode electrode. The anode electrode is an independent electrode for each light emitting element, but the cathode electrode may be a common electrode shared by all of the light emitting elements. When the driving current Ids is supplied from the driving transistor DT, electrons from the cathode electrode may be injected into the light emitting layer and holes from the anode electrode may be injected into the light emitting layer, so that each of the first and second light emitting elements ED1 and ED2 may allow fluorescent or phosphorescent materials to emit light through recombination of the electrons and the holes in the light emitting layer, thereby generating light of brightness proportional to a current value of the driving current.

The anode electrode of each of the first and second light emitting elements ED1 and ED2 may be connected to the second electrode of the driving transistor DT, and the cathode electrode thereof may be connected to the common power line VSSL. The light emitting element may emit light in response to the driving current Ids generated by the driving transistor DT.

In the display panel 110 according to one exemplary embodiment of the present disclosure, at least two light emitting elements ED1 and ED2 are included in one subpixel, and may emit light of the same color. In this case, at least two light emitting elements ED1 and ED2 may be connected to one circuit element to simultaneously emit light. Each of at least two light emitting elements ED1 and ED2 may correspond to each of at least two divided sub-light emission areas.

The display panel 110 according to one exemplary embodiment of the present disclosure may include a plurality of light emitting elements ED1 and ED2 in each of the subpixels SP1, SP2, SP3 and SP4. In the display panel 110 according to one exemplary embodiment of the present disclosure, when particles are introduced into one of the plurality of light emitting elements ED1 and ED2 to cause a short circuit between the anode electrode and the cathode electrode, the light emitting element in which the short circuit occurs and the light emitting element in which the short circuit does not occur may be separated from each other, so that only the light emitting element in which the short circuit occurs may become a dark spot.

In the display panel 110 according to one exemplary embodiment of the present disclosure, the light emitting element in which a short circuit occurs should be accurately detected in order to minimize a size of a dark spot area. In the display panel 110 according to one exemplary embodiment of the present disclosure, a high resistance area may be provided between one of the plurality of light emitting elements ED1 and ED2 and the driving transistor DT, and the light emitting element in which a short circuit occurs may be accurately detected using the high resistance area.

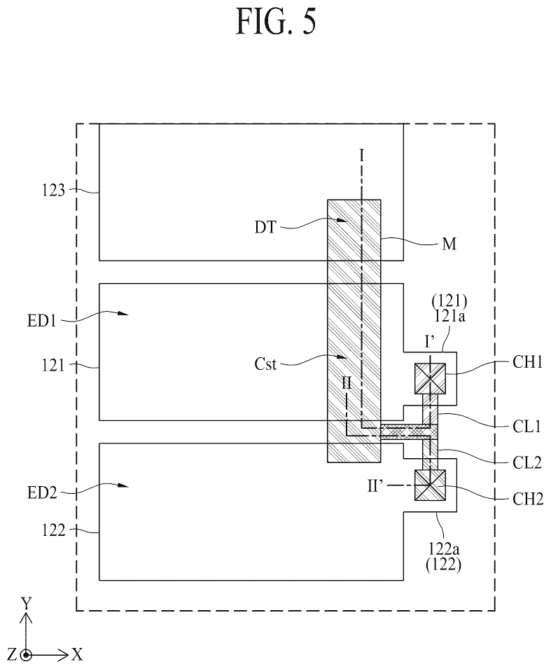

Hereinafter, a configuration for detecting a light emitting element in which a short circuit occurs and a method for detecting a light emitting element in which a short circuit occurs will be described in more detail with reference to FIGS. 5 to 17.

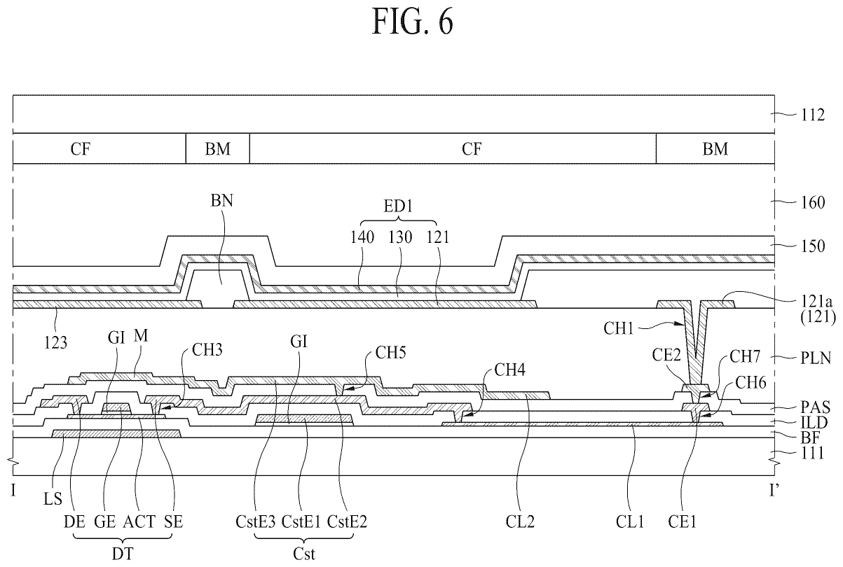

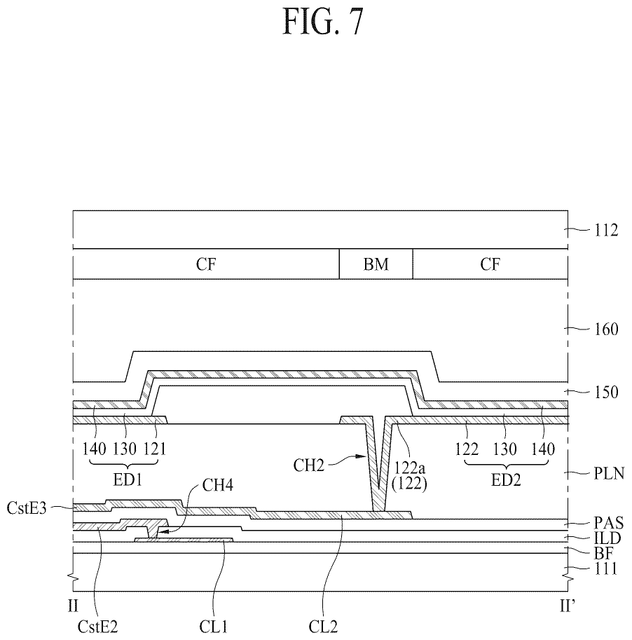

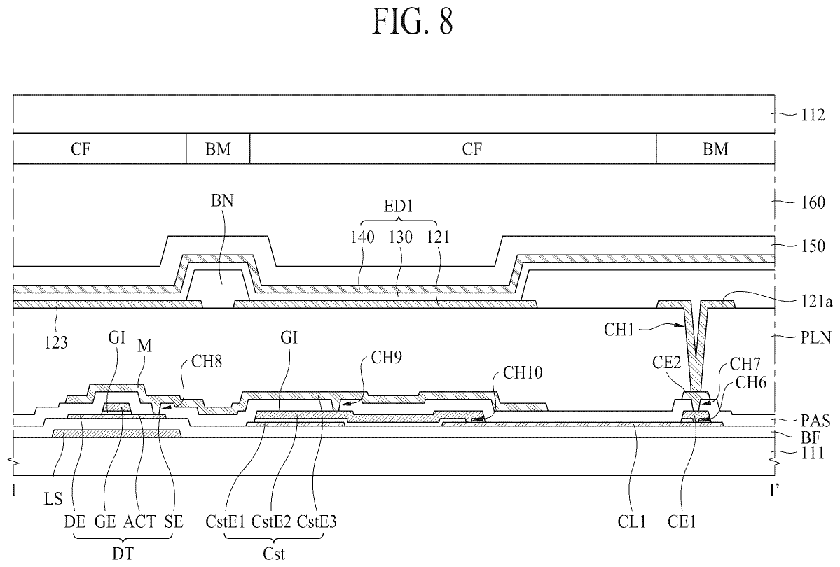

FIG. 5 is a plan view illustrating an example of first and second light emitting elements connected to one circuit element, FIG. 6 is a cross-sectional view illustrating an example of I-I′ of FIG. 5, FIG. 7 is a cross-sectional view illustrating an example of II-II′ of FIG. 5, and FIG. 8 is a cross-sectional view illustrating another example of I-I′ of FIG. 5.

Referring to FIG. 5, each of the plurality of subpixels SP1, SP2, SP3 and SP4 may include a circuit element including a capacitor Cst, a thin film transistor, etc., and at least two light emitting elements ED1 and ED2. The thin film transistor may include a switching transistor, a sensing transistor, and a driving transistor DT.

The driving transistor DT includes an active layer ACT, a gate electrode GE, a source electrode SE, and a drain electrode DE. The capacitor Cst may include three capacitor electrodes CstE1, CstE2 and CstE3, but is not limited thereto. In one exemplary embodiment, the capacitor Cst may include two capacitor electrodes.

Referring to FIGS. 5, 6 and 7, a light shielding layer LS may be provided on the first substrate 111. The light shielding layer LS may block external light and may prevent the characteristics of components disposed inside the display panel from changing due to external light. Additionally, the light shielding layer LS may include a metal material, and may transmit an electrical signal. The light shielding layer LS may be provided in an area in which the driving transistor DT is formed, to shield external light incident on the active layer ACT of the driving transistor DT.

The light shielding layer LS may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy, but not limited thereto.

A buffer layer BF may be provided on the light shielding layer LS. The buffer layer BF is to protect the driving transistor DT and the capacitor Cst from impurities such as hydrogen and moisture, which are permeated through the first substrate 111 that is vulnerable to moisture permeation, and may have a single-layered structure or a multi-layered structure, which includes an inorganic insulating material such as silicon oxide (SiOx), silicon nitride (SiNx) and aluminum oxide (Al₂O₃). For example, the buffer layer BF may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer BF may be excluded in accordance with the structure or properties of the display device.

The driving transistor DT and the capacitor Cst may be disposed on the buffer layer BF. The driving transistor DT may include an active layer, a gate electrode GE, a source electrode SE and a drain electrode DE, which are disposed on the buffer layer BF.

A gate insulating layer GI may be provided between the active layer ACT and the gate electrode GE. As shown in FIG. 6, the gate insulating layer GI may be formed to be patterned only in an area in which the gate electrode GE is provided, but is not limited thereto. In another exemplary embodiment, the gate insulating layer GI may be formed to cover the active layer ACT. The gate insulating layer GI can be formed of an inorganic layer, for example, silicon oxide (SiOx), silicon nitride (SiNx) and aluminum oxide (Al₂O₃), or a multi-layer thereof. For example, the gate insulating layer GI may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

An interlayer insulating layer ILD may be disposed between the gate electrode and the source and drain electrodes SE and DE. The source electrode SE and the drain electrode DE of the driving transistor DT may be connected to each of a source area and a drain area of the active layer ACT through a third contact hole CH3 passing through the interlayer insulating layer ILD.

Meanwhile, one of the source electrode SE and the drain electrode DE of the driving transistor DT may be connected to the light shielding layer LS through a contact hole passing through the interlayer insulating layer ILD and the buffer layer BF. The light shielding layer LS may be electrically connected to one of the source electrode SE and the drain electrode DE of the driving transistor DT, and thus may not operate as a floating gate. When the light shielding layer LS is floated without being connected to the other electrodes, a threshold voltage of the driving transistor DT may be changed by the floating light shielding layer LS. In the display panel 110 according to one exemplary embodiment of the present disclosure, the light shielding layer LS may be electrically connected to one of the source electrode SE and the drain electrode DE of the driving transistor DT, whereby a change in the threshold voltage of the driving transistor DT may be minimized.

The active layer ACT may be formed of a silicon-based semiconductor material or an oxide-based semiconductor material. The gate electrode GE, the source electrode SE and the drain electrode DE may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy, but not limited thereto.

The interlayer insulating layer ILD may have a single-layered structure or a multi-layered structure, which includes an inorganic insulating material such as silicon oxide (SiOx), silicon nitride (SiNx) and aluminum oxide (Al₂O₃). For example, the interlayer insulating layer ILD may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

Meanwhile, the capacitor Cst may include a first capacitor electrode CstE1, a second capacitor electrode CstE2, and a third capacitor electrode CstE3. At least one of the first capacitor electrode CstE1, the second capacitor electrode CstE2 or the third capacitor electrode CstE3 may be formed of the same material on the same layer as one of the active layer ACT, the gate electrode GE, the source electrode SE and the drain electrode DE of the driving transistor DT. For example, the first capacitor electrode CstE1 may be formed of the same material on the same layer as the gate electrode GE of the driving transistor DT as shown in FIG. 6, and the second capacitor electrode CstE2 may be formed of the same material on the same layer as the source electrode SE of the driving transistor DT. The second capacitor electrode CstE2 may be extended from the source electrode SE of the driving transistor DT, but is not limited thereto.

Meanwhile, FIG. 6 shows that the source electrode SE and the drain electrode DE of the driving transistor DT are provided in separate layers, but the present disclosure is not limited thereto. In another exemplary embodiment, as shown in FIG. 8, each of the source area and the drain area of the active layer ACT may correspond to the source electrode SE and the drain electrode DE of the driving transistor DT. In this case, as shown in FIG. 8, the first capacitor electrode CstE1 may be formed of the same material on the same layer as the active layer ACT of the driving transistor DT, and the second capacitor electrode CstE2 may be formed of the same material on the same layer as the gate electrode GE of the driving transistor DT. The second capacitor electrode CstE2 may be electrically connected to the source area of the active layer ACT, that is, the source electrode SE, through a metal layer M. The second capacitor electrode CstE2 may be connected to the metal layer M, which is connected to the source electrode SE of the driving transistor DT, through a ninth contact hole CH9.

An insulating layer PAS may be provided on the driving transistor DT. The insulating layer PAS may have a single-layered structure or a multi-layered structure, which includes an inorganic insulating material such as silicon oxide (SiOx), silicon nitride (SiNx) and aluminum oxide (Al₂O₃). For example, the insulating layer PAS may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The metal layer M may be disposed on the insulating layer PAS. The metal layer M may be disposed on the driving transistor DT, and may be provided to cover the gate electrode GE of the driving transistor DT on a plane. The metal layer M may be electrically connected to one of the source electrode SE and the drain electrode DE of the driving transistor DT. For example, the metal layer M may be electrically connected to the source electrode SE of the driving transistor DT through a fifth contact hole CH5 passing through the insulating layer PAS.

In one exemplary embodiment, as shown in FIGS. 5 and 6, the display panel 110 may be disposed such that the driving transistor DT of the subpixel overlaps an anode electrode 123 of adjacent subpixels. In this case, parasitic capacitance may occur between the driving transistor DT of the subpixel and the anode electrode 123 of the adjacent subpixels.

In detail, parasitic capacitance may occur between the gate electrode GE of the driving transistor DT of the subpixel and the anode electrode 123 of the adjacent subpixels. When the adjacent subpixels area driven, a voltage of the gate electrode of the driving transistor DT of the subpixel may be increased due to parasitic capacitance. As the voltage of the gate electrode GE of the driving transistor DT is increased, the driving voltage Vgs of the capacitor Cst may be increased. Further, the driving current Ids supplied to anode electrodes 121 and 122 of the subpixel may be increased. For this reason, while luminance is increased or reduced, the subpixel may not emit light with desired luminance. That is, a gray scale defect may occur in the subpixel.

In the display panel 110 according to one exemplary embodiment of the present disclosure, parasitic capacitance between the gate electrode GE of the driving transistor DT and the anode electrode 123 of the adjacent subpixels may be removed using the metal layer.

In detail, in the display panel 110 according to one exemplary embodiment of the present disclosure, the metal layer M may be disposed between the driving transistor DT of the subpixel and the anode electrode 123 of the adjacent subpixels. The metal layer M may be disposed on at least one of the source electrode SE or the drain electrode DE of the driving transistor DT, and thus may be electrically connected to one of the source electrode SE and the drain electrode DE of the driving transistor DT. As an example, the metal layer M may be disposed on the source electrode SE of the driving transistor DT, as shown in FIG. 6, and may be electrically connected to the source electrode SE of the driving transistor DT through the fifth contact hole CH5.

The metal layer M may be disposed in an area where the driving transistor DT of the subpixel overlaps the anode electrode 123 of the adjacent subpixels. The metal layer M may be extended from an area that overlaps the anode electrode 123 of the adjacent subpixels to an area in which the subpixel is disposed, and thus may be electrically connected to the anode electrode 120 of the subpixel. The metal layer M may be electrically connected to at least one of the anode electrode 121 of the first light emitting element ED1 or the anode electrode 122 of the second light emitting element ED2. At least one of the anode electrode 121 of the first light emitting element ED1 or the anode electrode 122 of the second light emitting element ED2 may be electrically connected to the source electrode SE of the driving transistor DT through the metal layer M.

The metal layer M may be formed to cover the gate electrode GE of the driving transistor DT in an area in which the driving transistor DT overlaps the anode electrode 123 of the adjacent subpixels on a plane. The gate electrode GE of the driving transistor DT may be in a floating state for a period at which the scan signal Scan (see FIG. 4) is not applied. The gate electrode GE in the floating state may be greatly affected by a peripheral signal. Therefore, when a voltage is applied to the anode electrode 123 of the adjacent subpixels disposed above the gate electrode GE, the voltage is also applied to the gate electrode GE in the floating state due to parasitic capacitance, whereby luminance of the subpixel may be increased.

In the display panel 110 according to one exemplary embodiment of the present disclosure, the metal layer M is disposed between the gate electrode GE of the driving transistor DT and the anode electrode 123 of the adjacent subpixels, and the metal layer M may be electrically connected to the source electrode SE or the drain electrode DE of the driving transistor DT, whereby parasitic capacitance may be removed. Therefore, in the display panel 110 according to one exemplary embodiment of the present disclosure, even though the voltage is applied to the anode electrode 123 of the adjacent subpixels, a change may not occur in the voltage of the gate electrode GE of the driving transistor DT.

Meanwhile, the metal layer M may be disposed to overlap the capacitor Cst in the area in which the subpixel is disposed. In this case, the metal layer M may become the third capacitor electrode CstE3 constituting the capacitor Cst in the area that overlaps the capacitor Cst.

In the display panel 110 according to one exemplary embodiment of the present disclosure, the metal layer M may be extended from the adjacent subpixels to the area in which the corresponding subpixel is disposed, so that the third capacitor electrode CstE3 may be formed, whereby the capacity of the capacitor Cst may be increased within a limited space.

In the display panel 110 according to one exemplary embodiment of the present disclosure, the metal layer M and the third capacitor electrode CstE3 may be formed simultaneously through a simple process. Therefore, in the display panel 110 according to one exemplary embodiment of the present disclosure, process optimization may be implemented, and production energy may be reduced.

The metal layer M may include molybdenum (Mo), titanium (Ti) or an alloy of molybdenum (Mo) and titanium (Ti), but is not limited thereto.

A planarization layer PLN for planarizing a step difference due to the driving transistor DT and the capacitor Cst may be provided on the metal layer M. The planarization layer PLN may be formed of an organic layer such as an acrylic resin, an epoxy resin, a phenolic resin, a polyamide resin, or a polyimide resin, but not limited thereto.

Light emitting elements ED1 and ED2, which include an anode electrode 120, a light emitting layer 130 and a cathode electrode 140, and a bank BN may be provided on the planarization layer PLN.

The anode electrode 120 may be provided on the planarization layer PLN. The anode electrode 120 may be provided for each of the subpixels SP1, SP2, SP3 and SP4. One anode electrode 120 may be formed in the first subpixel SP1, another anode electrode 120 may be formed in the second subpixel SP2, still another anode electrode 120 may be formed in the third subpixel SP3, and further still another electrode 120 may be formed in the fourth subpixel SP4.

The anode electrode 120 may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti).

The anode electrode 120 may be electrically connected to the driving transistor DT to receive a data current from the driving transistor DT. In detail, the anode electrode 120 respectively provided in the subpixels SP1, SP2, SP3 and SP4 may be provided as a plural number, and the plurality of anode electrodes 121 and 122 may be connected to each other through separate anode connection lines CL1 and CL2.

The anode electrode 120 may include a first anode electrode 121 and a second anode electrode 122, and may be spaced apart from each other in the first direction (X-axis direction) or the second direction (Y-axis direction). As the number of electrodes 121 and 122 included in one anode electrode 120 becomes smaller, an aperture ratio may be increased, but a size of an area that becomes a dark spot due to particles may be increased and thus yield may be reduced. On the other hand, as the number of electrodes 121 and 122 included in one anode electrode 120 is larger, the aperture ration may be reduced, but the size of the area that becomes a dark spot due to particles may be reduced and thus yield may be increased.

Hereinafter, for convenience of description, the description will be based on that the anode electrode 120 includes the first anode electrode 121 and the second anode electrode 122.

The first anode electrode 121 may be disposed in the first sub-light emission areas EA11, EA21, EA31 and EA41, and may constitute the first light emitting element ED1 together with the light emitting layer 130 and the cathode electrode 140. The second anode electrode 122 may be disposed in the second sub-light emission areas EA12, EA22, EA32 and EA42, and may constitute the second light emitting element ED2 together with the light emitting layer 130 and the cathode electrode 140. The first anode electrode 121 and the second anode electrode 122 may be disposed to be spaced apart from each other on the same layer.

The anode connection lines CL1 and CL2 may be for connecting the first anode electrode 121 and the second anode electrode 122 to the driving transistor DT, and may include a first anode connection line CL1 and a second anode connection line CL2 as shown in FIG. 5.

The first anode connection line CL1 may electrically connect the first anode electrode 121 with the driving transistor DT. The first anode connection line CL1 may be electrically connected to one of the source electrode SE and the drain electrode DE of the driving transistor DT at one end. For example, the second capacitor electrode CstE2 may be electrically connected to the first anode connection line CL1 through a fourth contact hole CH4. Since the second capacitor electrode CstE2 is electrically connected to the source electrode SE of the driving transistor DT, the first anode connection line CL1 may be electrically connected to the source electrode SE of the driving transistor DT through the second capacitor electrode CstE2.

The first anode electrode 121 may include a first protrusion 121a protruded outward at one side. The first anode connection line CL1 may be extended by a predetermined length from one end in an outward direction. In addition, the first anode connection line CL1 may be extended to be bent so that the other end thereof may at least partially overlap the first protrusion 121a of the first anode electrode 121.

The first anode connection line CL1 may be electrically connected to the first protrusion 121a of the first anode electrode 121 at the other end. The first anode connection line CL1 may be disposed on a different layer from the first anode electrode 121, and may be electrically connected to the first anode electrode 121 through at least one connection electrode CE1 or CE2.

For example, as shown in FIG. 6, the first anode connection line CL1 may be electrically connected to the first anode electrode 121 through the first connection electrode CE1 and the second connection electrode CE2. The first connection electrode CE1 may be connected to the first anode connection line CL1 through a sixth contact hole CH6, and the second connection electrode CE2 may be connected to the first connection electrode CE1 through a seventh contact hole CH7. The first protrusion 121a of the first anode electrode 121 is connected to the second connection electrode CE2 through a first contact hole CH1, and thus may be electrically connected to the first anode connection line CL1 through the first connection electrode CE1 and the second connection electrode CE2, but the present disclosure is not limited thereto.

As another example, the first anode connection line CL1 may be electrically connected to the first protrusion 121a of the first anode electrode 121 through one connection electrode CE1. As another example, the first anode connection line CL1 may be directly connected to the first protrusion 121a of the first anode electrode 121.

Meanwhile, in another exemplary embodiment, as shown in FIG. 8, each of the source area and the drain area of the active layer ACT may correspond to the source electrode SE and the drain electrode DE of the driving transistor DT. In this case, the second capacitor electrode CstE2 may be electrically connected to the first anode connection line CL1 through a tenth contact hole CH10 passing through the gate insulating layer GI. Since the second capacitor electrode CstE2 is electrically connected to the source electrode SE of the driving transistor DT through the metal layer M, the first anode connection line CL1 may be electrically connected to the source electrode SE of the driving transistor DT through the metal layer M and the second capacitor electrode CstE2.

The second anode connection line CL2 may electrically connect the second anode electrode 122 with the driving transistor DT. The second anode connection line CL2 may be electrically connected to one of the source electrode SE and the drain electrode DE of the driving transistor DT at one end. For example, the second anode connection line CL2 may be extended from the third capacitor electrode CstE3. Since the third capacitor electrode CstE3 is electrically connected to the source electrode SE of the driving transistor DT, the second anode connection line CL2 may be electrically connected to the source electrode SE of the driving transistor DT through the third capacitor electrode CstE3.

The second anode electrode 122 may include a second protrusion 122a protruded outward at one side. The second anode connection line CL2 may be extended by a predetermined length from one end in an outward direction. In addition, the second anode connection line CL2 may be extended to be bent so that the other end thereof may at least partially overlap the second protrusion 122a of the second anode electrode 122.

The second anode connection line CL2 may be electrically connected to the second protrusion 122a of the second anode electrode 122 at the other end. As shown in FIG. 7, the second anode connection line CL2 may be disposed on a different layer from the second anode electrode 122, and may be electrically connected to the second protrusion 122a of the second anode electrode 122 through a second contact hole CH2, but is not limited thereto. As another example, the second anode connection line CL2 may be electrically connected to the second protrusion 122a of the second anode electrode 122 through at least one connection electrode.

In the display panel 110 according to one exemplary embodiment of the present disclosure, the first anode connection line CL1 connected to the first anode electrode 121 and the second anode connection line CL2 connected to the second anode electrode 122 may be formed to have different resistances from each other. In detail, the first anode connection line CL1 may have resistance greater than that of the second anode connection line CL2.

The first anode connection line CL1 may be formed of a silicon-based semiconductor material or an oxide-based semiconductor material, and thus may have first high resistance. In one exemplary embodiment, as shown in FIG. 6, the first anode connection line CL1 may be formed of the same material on the same layer as the active layer ACT of the driving transistor DT.

The second anode connection line CL2 may be made of a material different from that of the first anode connection line CL1. The second anode connection line CL2 may be made of a material having resistance that is relatively low as compared with the first anode connection line CL1. For example, the second anode connection line CL2 may include molybdenum (Mo), titanium (Ti), or an alloy (MoTi) of molybdenum (Mo) and titanium (Ti), but not limited thereto.

The second anode connection line CL2 may be provided on a different layer from the first anode connection line CL1. The second anode connection line CL2 may be provided on the driving transistor DT. In one exemplary embodiment, the second anode connection line CL2 may be formed of the same material on the same layer as the metal layer M as shown in FIG. 7.

Alternatively, the first anode connection line CL1 may have resistance smaller than that of the second anode connection line CL2. The first anode connection line CL1 may include molybdenum (Mo), titanium (Ti), or an alloy (MoTi) of molybdenum (Mo) and titanium (Ti) and thus may have first low resistance. The second anode connection line CL2 may be formed of a silicon-based semiconductor material or an oxide-based semiconductor material, and thus may have second high resistance. However, the present disclosure is not limited thereto.

The display panel 110 according to one exemplary embodiment of the present disclosure is characterized in that the first anode connection line CL1 connected to the first anode electrode 121 and the second anode connection line CL2 connected to the second anode electrode 122 have different resistances from each other. In the display panel 110 according to one exemplary embodiment of the present disclosure, the electrode, in which a short circuit occurs, of the first anode electrode 121 and the second anode electrode 122, may be detected using a difference in resistance between the first anode connection line CL1 and the second anode connection line CL2. A detailed description of a method of detecting the electrode in which the short circuit occurs will be described later with reference to FIGS. 11 to 17.

The bank BN may be provided on the planarization layer PLN. The bank BN may be disposed at a boundary between the plurality of subpixels SP and suppress a color mixture of light beams from the plurality of subpixels SP. The bank BN may be formed to cover an edge of each of the anode electrodes 120 and expose a portion of each of the anode electrodes 120. Therefore, the bank BN may prevent a problem in which the light emission efficiency is deteriorated due to the concentration of current on the end of each of the anode electrodes 120.

The bank BN may define the light emission areas EA11, EA12, EA21, EA22, EA31, EA32, EA41 and EA42 of each of the subpixels SP1, SP2, SP3 and SP4. The light emission areas EA11, EA12, EA21, EA22, EA31, EA32, EA41 and EA42 of each of the subpixels SP1, SP2, SP3 and SP4 represent areas where the anode electrode 120, the light emitting layer 130 and the cathode electrode 140 are sequentially stacked to emit light by combination of holes from the anode electrode 120 and electrons from the cathode electrode 140 in the light emitting layer 130. In this case, the area where the bank BN is formed does not emit light, and thus becomes a non-light emission area (not shown), and the area where the bank BN is not formed and the anode electrode 120 is exposed may become the light emission areas EA11, EA12, EA21, EA22, EA31, EA32, EA41 and EA42.

The bank BN may be formed of an organic layer such as an acrylic resin, an epoxy resin, a phenolic resin, a polyamide resin, or a polyimide resin. Meanwhile, the bank BN may include an inorganic insulating material, such as silicon nitride (SiNx) or silicon oxide (SiOx), or the bank BN may be formed of black resin. However, the present disclosure is not limited thereto.

The light emitting layer 130 may be provided on the anode electrode 120. The light emitting layer 130 may include a hole transporting layer, an emission material layer and an electron transporting layer. In this case, when a voltage is applied to the anode electrode 120 and the cathode electrode 140, holes and electrons move to the light emitting layer through the hole transporting layer and the electron transporting layer, respectively, and are combined with each other in the light emitting layer to emit light.

In one exemplary embodiment, the light emitting layer 130 may be a common layer commonly formed in the subpixels SP1, SP2, SP3 and SP4. In this case, the light emitting layer may be a white light emitting layer for emitting white light. In this case, the light emitting layer 130 may be formed not only in the subpixels SP1, SP2, SP3 and SP4 but also in the non-light emission area (not shown) between the subpixels SP1, SP2, SP3 and SP4. The light emitting layer 130 may be continuously formed between the subpixels SP1, SP2, SP3 and SP4.

In another exemplary embodiment, the emission material layer of the light emitting layer 130 may be formed for each of the subpixels SP1, SP2, SP3 and SP4. For example, a red light emitting layer for emitting red light may be formed in the first subpixel SP1, a green light emitting layer for emitting green light may be formed in the second subpixel SP2, a blue light emitting layer for emitting blue light may be formed in the third subpixel SP3, and a white light emitting layer for emitting white light may be formed in the fourth subpixel SP4. However, the present disclosure is not limited thereto.

The cathode electrode 140 may be provided on the light emitting layer 130. The cathode electrode 140 may be a common layer commonly formed in the subpixels SP1, SP2, SP3 and SP4 to apply the same voltage. The cathode electrode 140 may be formed not only in the light emission areas EA11, EA12, EA21, EA22, EA31, EA32, EA41 and EA42 of the subpixels SP1, SP2, SP3 and SP4 but also in the non-light emission area (not shown) between the subpixels SP1, SP2, SP3 and SP4. The cathode electrode 140 may be continuously formed between the subpixels SP1, SP2, SP3 and SP4.

The cathode electrode 140 may be formed of a transparent conductive material (TCO) such as ITO or IZO capable of transmitting light or a semi-transmissive conductive material such as magnesium (Mg), silver (Ag) or an alloy of magnesium (Mg) and silver (Ag). When the cathode electrode 140 is formed of a semi-transmissive conductive material, light emission efficiency may be increased by a micro cavity.

An encapsulation layer 150 may be provided on the light emitting elements ED1 and ED2. The encapsulation layer 150 may be formed on the cathode electrode 140 to cover the cathode electrode 140. The encapsulation layer 150 serves to prevent oxygen or moisture from being permeated into the light emitting layer 130 and the cathode electrode 140. To this end, the encapsulation layer 150 may include at least one inorganic layer and further include at least one organic layer.

For example, the encapsulation layer 150 has a structure in which inorganic encapsulation layers and organic encapsulation layers are alternately stacked, such that the encapsulation layer 150 may protect the light-emitting element while inhibiting moisture or oxygen from penetrating into the light-emitting element. For example, the encapsulation layer 150 may have a multi-insulating film structure in which organic films and inorganic films are stacked alternately. The inorganic film can block permeation of moisture or oxygen. The organic film may planarize a surface of the inorganic film. When the organic film and the inorganic film are stacked in multiple layers, a movement path of moisture or oxygen may be longer than that of a single layer, thereby effectively blocking the permeation of moisture and oxygen affecting the light emitting layer. For example, the encapsulation layer 150 includes a first inorganic encapsulation layer, a first organic encapsulation layer, and a second inorganic encapsulation layer stacked sequentially. For example, the encapsulation layer 150 includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer 150 is not limited to three or five layers, for example, n layers alternately stacked between inorganic encapsulation layer and organic encapsulation layer (where n is an integer greater than 3) may be included.

A color filter CF may be provided on one surface of the second substrate 112, which faces the first substrate 111. The color filter CF may be formed to be patterned for each of the subpixels SP1, SP2, SP3 and SP4.

In detail, the color filter CF may include a first color filter, a second color filter, a third color filter, and a fourth color filter. The first color filter may be disposed to correspond to the light emission areas EA11 and EA12 of the first subpixel SP1, and may be a red color filter for transmitting red light. The second color filter may be disposed to correspond to the light emission areas EA21 and EA22 of the second subpixel SP2, and may be a green color filter for transmitting green light. The third color filter may be disposed to correspond to the light emission areas EA31 and EA32 of the third subpixel SP3, and may be a blue color filter for transmitting blue light. The fourth color filter may be disposed to correspond to the light emission areas EA41 and EA42 of the fourth subpixel SP4, and may be a transparent organic layer.

A black matrix BM may be provided between the color filters CF. The black matrix BM may be provided between the subpixels SP1, SP2, SP3 and SP4 to prevent color mixture from occurring between adjacent subpixels SP1, SP2, SP3 and SP4. Also, the black matrix may prevent light incident from the outside from being reflected on a plurality of signal lines, e.g., scan lines, data lines, pixel power lines, common power lines and reference lines, which are provided between the subpixels SP1, SP2, SP3 and SP4.

Such a black matrix BM may include a material that absorbs light, for example, a black dye that absorbs all light of a visible wavelength band.

A filler 160 may be provided between the first substrate 111 provided with the light emitting elements ED1 and ED2 and the second substrate 112 provided with the color filter CF and the black matrix BM. In this case, a thermosetting resin or a UV curable resin may be used as the filler 160, and the filler 160 may be made of an organic material having adhesive properties. In one exemplary embodiment, the filler 160 may include a material that absorbs hydrogen, but not limited thereto.

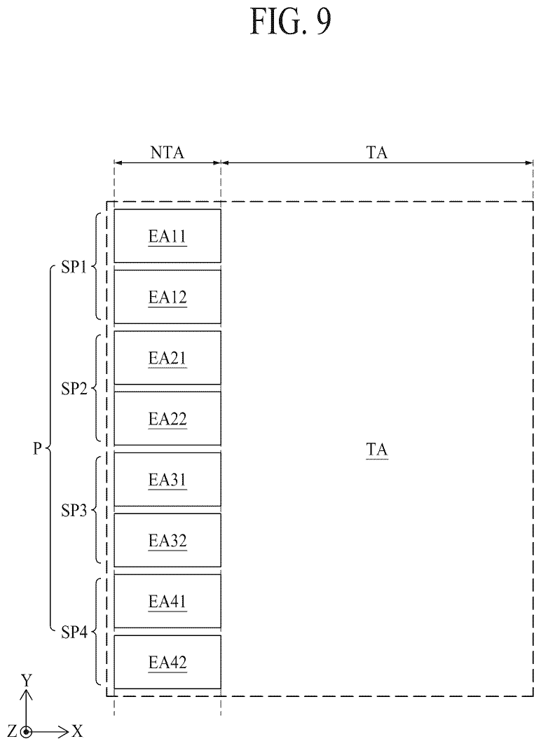

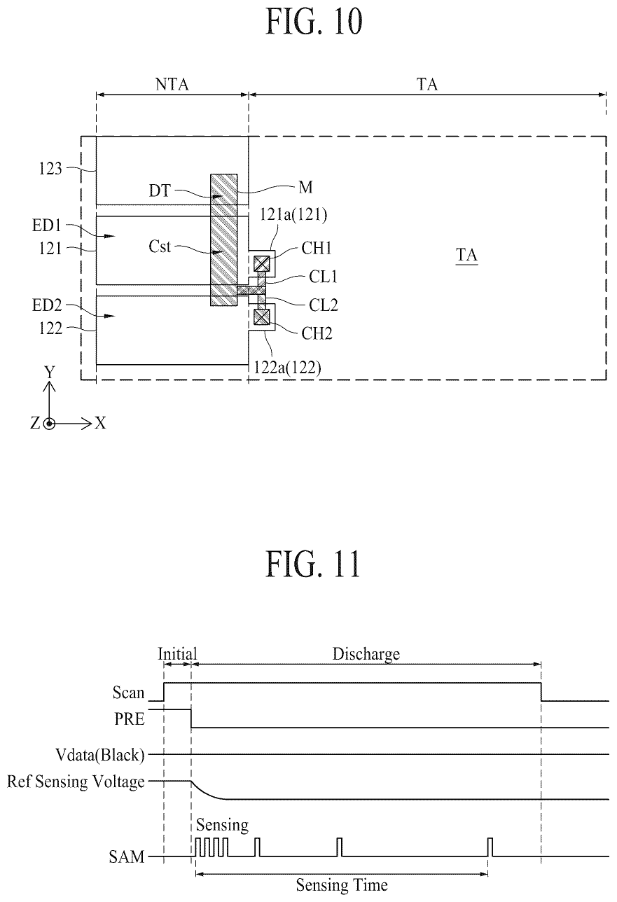

FIG. 9 is a schematic view illustrating another exemplary embodiment of a pixel provided in an area A of FIG. 2, and FIG. 10 is a plan view illustrating an example of first and second light emitting elements connected to one circuit element in FIG. 9.

The display panel 110 shown in FIGS. 9 and 10 is different from the display panel 110 shown in FIGS. 3 to 8 in that it includes a transmissive area TA. The following description will be based on differences from the display panel 110 shown in FIGS. 3 to 8, and the description substantially the same as that in FIGS. 3 to 8 will be omitted.

The display panel 110 according to another exemplary embodiment of the present disclosure may include a display area DA and a non-display area NDA (FIG. 2). As shown in FIG. 9, the display area DA may include a first area NTA in which a plurality of subpixels SP1, SP2, SP3 and SP4 are disposed, and a second area TA in which the plurality of subpixels SP1, SP2, SP3 and SP4 are not disposed. The first area NTA may be a non-transmissive area that does not transmit most of light incident from the outside. The second area TA may be a transmissive area through which most of light incident from the outside passes. For example, the transmissive area TA may be an area in which light transmittance is greater than x %, and the non-transmissive area NTA may be an area in which light transmittance is smaller than β%. In this case, a may be a value greater than β. A user may view an object or a background, which is positioned on a rear surface of the display panel 110, due to the transmissive areas TA.

The non-transmissive area NTA may include light emission areas EA1, EA2, EA3 and EA4 provided with a plurality of subpixels SP1, SP2, SP3 and SP4 to emit light and a non-light emission area provided between the light emission areas EA1, EA2, EA3 and EA4. Also, a plurality of signal lines DL, VDDL, VSSL and REFL (see FIG. 4) and circuit elements DT, SWT, SET and Cst (see FIG. 4) may be disposed in the non-transmissive area NTA. The plurality of signal lines DL, VDDL, VSSL and REFL may be extended in the second direction (e.g., Y-axis direction) in the non-transmissive area NTA disposed between the transmissive areas TA.

In the display panel 110 according to another exemplary embodiment of the present disclosure, since the transmissive area TA is provided in the display area DA, a size of the non-transmissive area NTA, which includes the light emission areas EA1, EA2, EA3 and EA4, is reduced. In the display panel 110 according to another exemplary embodiment of the present disclosure, since a plurality of light emitting elements, a plurality of signal lines and a plurality of circuit elements should be provided in the narrow non-transmissive area NTA, the plurality of light emitting elements may be inevitably formed to overlap the plurality of signal lines and the plurality of circuit elements. Therefore, in the display panel 110 according to another exemplary embodiment of the present disclosure, the plurality of signal lines DL, VDDL, VSSL and REFL (FIG. 4) and the circuit elements DT, SWT, SET and Cst (FIG. 4) may be disposed to overlap the light emission areas EA1, EA2, EA3 and EA4.

The first light emitting element ED1 and the second light emitting element ED2, which are provided in each of the subpixels SP1, SP2, SP3 and SP4, may be disposed to be spaced apart from each other in the first direction (X-axis direction) or the second direction (Y-axis direction) in the non-transmissive area NTA. The first light emitting element ED1 may be disposed in the first sub-light emission area EA11, EA21, EA31 and EA41, and may include a first anode electrode 121, a light emitting layer 130, and a cathode electrode 140. The second light emitting element ED2 may be disposed in the second sub-light emission areas EA12, EA22, EA32 and EA42, and may include a second anode electrode 122, a light emitting layer 130, and a cathode electrode 140.

The first light emitting element ED1 and the second light emitting element ED2 may be connected to one circuit element by using the anode connection lines CL1 and CL2. The anode connection lines CL1 and CL2 are for connecting the first anode electrode 121 and the second anode electrode 122 to the driving transistor DT, and may include a first anode connection line CL1 and a second anode connection line CL2 as shown in FIG. 10.

The first anode connection line CL1 may electrically connect the first anode electrode 121 with the driving transistor DT. The first anode connection line CL1 may be electrically connected to one of the source electrode SE and the drain electrode DE of the driving transistor DT at one end. For example, the first anode connection line CL1 may be electrically connected to the source electrode SE of the driving transistor DT through the capacitor electrode CstE2 (see FIG. 6) of the capacitor Cst electrically connected to the source electrode SE of the driving transistor DT.

The first anode electrode 121 may include a first protrusion 121a protruded from one side toward the transmissive area TA. The first anode connection line CL1 may be extended by a predetermined length from one end toward the transmissive area TA. In addition, the first anode connection line CL1 may be extended to be bent so that the other end thereof may at least partially overlap the first protrusion 121a of the first anode electrode 121. The first anode connection line CL1 may be electrically connected to the first protrusion 121a of the first anode electrode 121 at the other end.

The second anode connection line CL2 may electrically connect the second anode electrode 122 with the driving transistor DT. The second anode connection line CL2 may be electrically connected to one of the source electrode SE and the drain electrode DE of the driving transistor DT at one end. For example, the second anode connection line CL2 may be electrically connected to the source electrode SE of the driving transistor DT through the capacitor electrode CstE3 (see FIG. 6 and FIG. 7) of the capacitor Cst electrically connected to the source electrode SE of the driving transistor DT.

The second anode electrode 122 may include a second protrusion 122a protruded from one side toward the transmissive area TA. The second anode connection line CL2 may be extended by a predetermined length from one end toward the transmissive area TA. In addition, the second anode connection line CL2 may be extended to be bent so that the other end thereof may at least partially overlap the second protrusion 122a of the second anode electrode 122. The second anode connection line CL2 may be electrically connected to the second protrusion 122a of the second anode electrode 122 at the other end.

The first anode connection line CL1 and the second anode connection line CL2 may be disposed between the first protrusion 121a of the first anode electrode 121 and the second protrusion portion 122a of the second anode electrode 122. The first anode connection line CL1 and the second anode connection line CL2 may be formed to be protruded from one side of the non-transmissive area NTA toward the transmissive area TA. An area in which the first anode connection line CL1 and the second anode connection line CL2 are formed in the protruded area may become the non-transmissive area NTA. Therefore, the size of the transmissive area TA of the display panel 110 may be reduced by the first anode connection line CL1 and the second anode connection line CL2, which are protruded.

In the display panel 110 according to one exemplary embodiment of the present disclosure, at least a portion of the first anode connection line CL1 and at least a portion of the second anode connection line CL2 may overlap each other, so that the size of the area in which the first anode connection line CL1 and the second anode connection line CL2 are formed may be reduced. The first anode connection line CL1 may include a first area extended from one end connected to the driving transistor DT toward the transmissive area TA, and a second area extended from a point bent toward the first protrusion 121a of the first anode electrode 121 to the other end connected to the first protrusion 121a of the first anode electrode 121. The second anode connection line CL2 may include a first area extended from one end connected to the driving transistor DT toward the transmissive area TA, and a second area extended from a point bent toward the second protrusion 122a of the second anode electrode 122 to the other end connected to the second protrusion 122a of the second anode electrode 122.

In the display panel 110 according to one exemplary embodiment of the present disclosure, the first area of the first anode connection line CL1 and the first area of the second anode connection line CL2 may be formed to overlap each other. Therefore, in the display panel 110 according to one exemplary embodiment of the present disclosure, the size of the area in which the first anode connection line CL1 and the second anode connection line CL2 are formed may be reduced, and loss of transparency due to the first anode connection line CL1 and the second anode connection line CL2 may be reduced.

Meanwhile, in the display panel 110 according to one exemplary embodiment of the present disclosure, the second area of the first anode connection line CL1 and the second area of the second anode connection line CL2 may be formed so as not to overlap each other. The display panel 110 according to one exemplary embodiment of the present disclosure may include a cutting area in each of the second area of the first anode connection line CL1 and the second area of the second anode connection line CL2 to cut a defective light emitting element with a laser when a defect occurs in the first light emitting element ED1 or the second light emitting element ED2.

Hereinafter, a method of detecting a defective light emitting element and a method of repairing the defective light emitting element will be described in detail with reference to FIGS. 11 to 17.

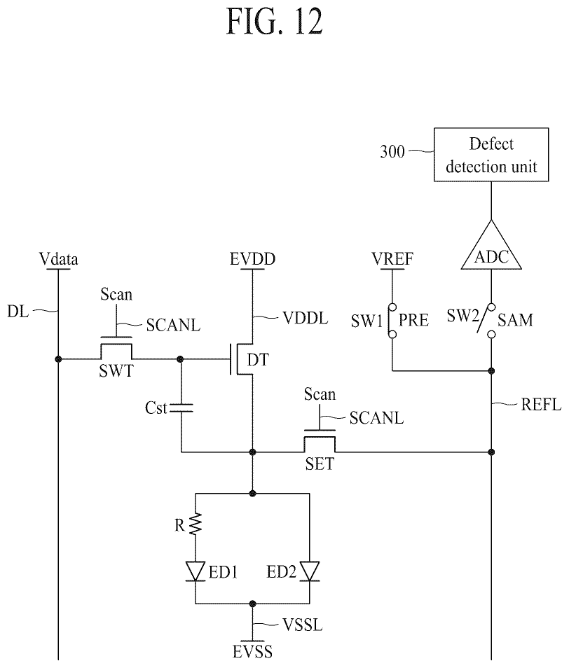

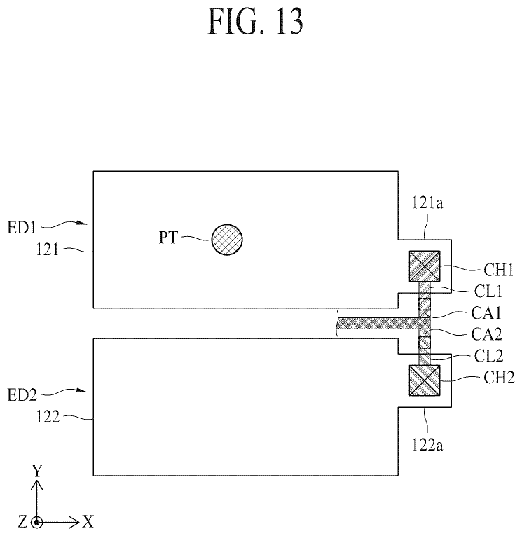

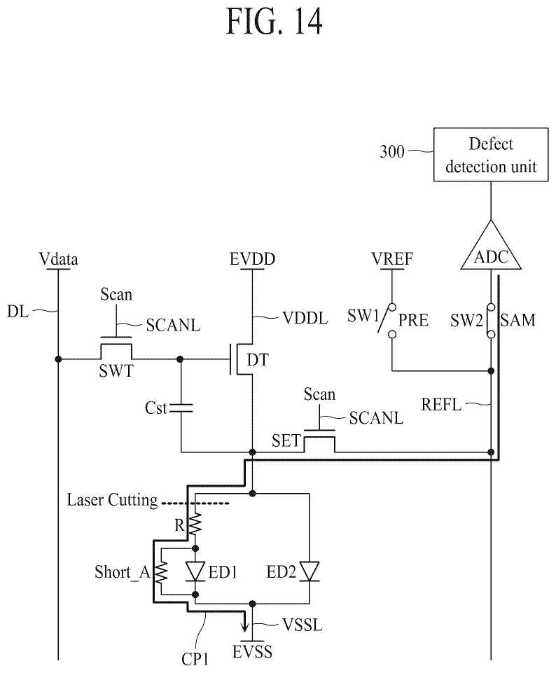

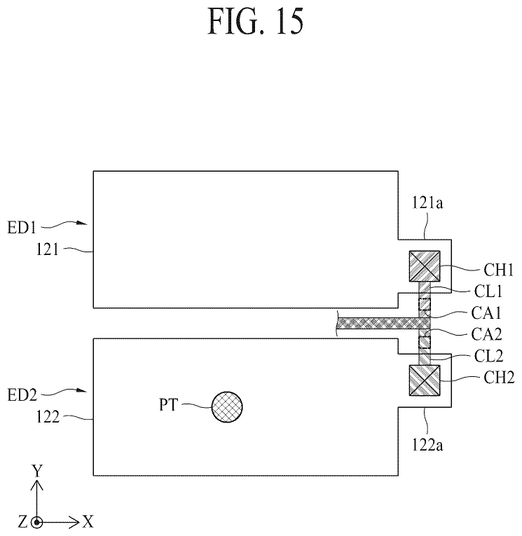

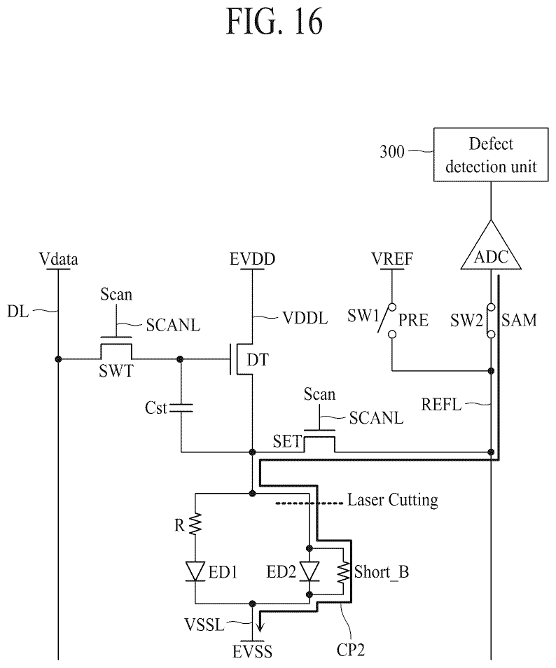

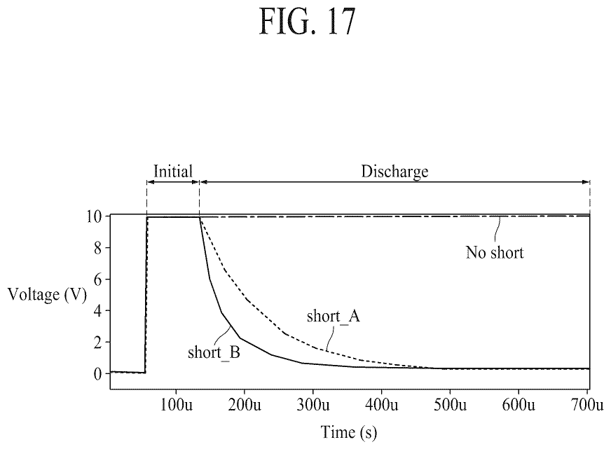

FIG. 11 is a view illustrating an example of driving waveforms in a defect inspection mode, FIG. 12 is a view illustrating an operation of a subpixel for an initial period, FIG. 13 is a view illustrating an example in which a defect occurs in a first light emitting element, FIG. 14 is a view illustrating an operation of a subpixel for a discharge period when a defect occurs in a first light emitting element, FIG. 15 is a view illustrating an example in which a defect occurs in a second light emitting element, FIG. 16 is a view illustrating an operation of a subpixel for a discharge period when a defect occurs in a second light emitting element, and FIG. 17 is a graph illustrating a change of a sensing voltage when a defect occurs in a first light emitting element and when a defect occurs in a second light emitting element.

As described in FIGS. 3 to 10, in the display panel 110 according to one exemplary embodiment of the present disclosure, each of the divided anode electrodes 121 and 122 may be connected to different resistance, and may determine an occurrence position of a short circuit through electrical sensing. In detail, in the display panel 110 according to one exemplary embodiment of the present disclosure, the first anode connection line CL1 connected to the first anode electrode 121 and the second anode connection line CL2 connected to the second anode electrode 122 may have different resistances from each other. For example, the first anode connection line CL1 may have resistance higher than that of the second anode connection line CL2.

In the display panel 110 according to one exemplary embodiment of the present disclosure, the position of the electrode where the short circuit occurs may be determined using a resistance difference between the first anode connection line CL1 and the second anode connection line CL2. In the display panel 110 according to one exemplary embodiment of the present disclosure, a defect inspection for detecting a defective subpixel may be performed before a product is released. A defect inspection period may include an initial period and a discharge period, as shown in FIG. 11.

First, the scan signal may be activated by a gate-on voltage during the initial period and the discharge period. For example, the gate-on voltage of the scan signal Scan may be a high level.

The switching transistor SWT and the sensing transistor SET may be turned on in response to the scan signal Scan. The switching transistor SWT may connect the data line DL to the first electrode of the capacitor Cst in response to the gate-on voltage of the scan signal Scan. The switching transistor SWT may supply the data voltage Vdata supplied through the data line DL to the first electrode of the capacitor Cst. In this case, a voltage corresponding to a black voltage may be supplied as the data voltage Vdata. For example, the data voltage Vdata may be supplied with OV.

The sensing transistor SET may connect the reference line REFL to the second electrode of the capacitor Cst in response to the gate-on voltage of the scan signal Scan. When the initialization voltage Vref (or the reference voltage) is applied to the reference line REFL, the sensing transistor SET may supply the reference voltage Vref (or the initialization voltage, or Ref Sensing Voltage) supplied through the reference line REFL to the second electrode of the capacitor Cst.

The reference line REFL may be connected to the reference voltage source VREF or the AD converter ADC in accordance with the control signal. The first switch SW1 may connect or disconnect the reference voltage source VREF to or from the reference line REFL in accordance with the initialization control signal PRE.

At the initialization period, the initialization control signal PRE may be activated by a turn-on voltage. For example, the turn-on voltage of the initialization control signal PRE may be a high level. As shown in FIG. 12, when the first switch SW1 is turned on in accordance with the initialization control signal PRE of a turn-on level, the reference line REFL may be connected to the reference voltage source VREF and thus initialized to the reference voltage Vref (or the initialization voltage). The reference line REFL may be connected to the reference voltage source VREF during the initial period to charge a voltage applied from the reference voltage source VREF.

When the sensing transistor SET is turned on, the reference voltage Vref (or the initialization voltage) applied through the reference line REFL may be transferred to the second electrode of the capacitor Cst. Also, the reference voltage Vref (or the initialization voltage) may be applied to the source electrode of the driving transistor DT.

At the discharge period, the initialization control signal PRE may be deactivated by a turn-off voltage. For example, the turn-off voltage of the initialization control signal PRE may be a low level. When the first switch SW1 is turned off in accordance with the initialization control signal PRE of a turn-off level, the reference line REFL may be separated from the reference voltage source VREF. The reference line REFL may be separated from the reference voltage source VREF during the discharge period to discharge at least a part of the reference voltage Vref (or the initialization voltage).

The second switch SW2 may connect or disconnect the AD converter ADC to or from the reference line REFL in accordance with the sampling control signal SAM. The sampling control signal SAM may be activated by the turn-on voltage during the discharge period. For example, the turn-on voltage of the sampling control signal SAM may be high level. As shown in FIG. 11, the sampling control signal SAM may be activated by the turn-on voltage at least once during the discharge period. When the second switch SW2 is turned on in accordance with the sampling control signal SAM of the turn-on level, the reference line REFL may be connected to the AD converter ADC. In this case, the AD converter ADC may be connected to the reference line REFL to sense the voltage charged in the reference line REFL.

Also, when the second switch SW2 is turned off in accordance with the sampling control signal SAM of the turn-off level, the reference line REFL may be separated from the AD converter ADC.

The display panel 110 according to one exemplary embodiment of the present disclosure may further include a defect detection unit 300 (e.g., a circuit) to determine an element in which a defect has occurred based on a voltage sensed by the AD converter ADC. The AD converter ADC may convert the sensed voltage into digital sensing data and output the digital sensing data to the defect detection unit 300. In this case, the defect detection unit 300 may be a component included in an external circuit board (not shown) or a component included in an external defect inspection equipment.

The defect detection unit 300 may determine an element in which a defect has occurred based on the sensing voltage. In detail, the reference line REFL may be connected to the reference voltage source VREF during the initialization period and charged with a voltage (reference voltage or initialization voltage). Meanwhile, the reference line REFL may be separated from the reference voltage source VREF during the discharge period. The scan signal Scan is activated by the gate-on voltage during the discharge period and, thus, the first light emitting element ED1 and the second light emitting element ED2 may be connected to the reference line REFL together with the switching transistor SWT, the sensing transistor SET and the driving transistor DT.

When the first light emitting element ED1 and the second light emitting element ED2 are normal elements (No short), since internal resistance of each of the first light emitting element ED1 and the second light emitting element ED2 is very large, the current passing through the first light emitting element ED1 and the second light emitting element ED2 may be very small. Therefore, as shown in FIG. 17, the voltage (reference voltage or initialization voltage) charged in the reference line REFL may be maintained without being discharged, or may be discharged at a very slow speed even when being discharged.

When the voltage sensed through the AD converter ADC approaches the voltage (reference voltage or initialization voltage), the defect detection unit 300 may determine that both the first light emitting element ED1 and the second light emitting element ED2, which are included in the corresponding subpixel, are normal elements.

On the other hand, a short_A may occur in the first light emitting element ED1 of the first light emitting element ED1 and the second light emitting element ED2. As shown in FIG. 13, particles PT may occur on the first anode electrode 121 of the first light emitting element ED1, and a short circuit may occur when the first anode electrode 121 and the cathode electrode 140 of the first light emitting element ED1 are in contact with each other. For this reason, a first current path CP1 in which the first anode electrode 121 and the cathode electrode 140 of the first light emitting element ED1 are directly connected to each other without passing through the first light emitting element ED1 may occur as shown in FIG. 14. Since the resistance in the area where the first anode electrode 121 and the cathode electrode 140 of the first light emitting element ED1 are short-circuited is much smaller than the internal resistance of the first light emitting element ED1, a large amount of current may flow. Therefore, as shown in FIG. 17, when a defect occurs in the first light emitting element ED1 (short_A), the voltage charged in the reference line REFL (reference voltage or initialization voltage) may be discharged at a faster speed than when the first and second light emitting elements ED1 and ED2 are normal (no short).

Meanwhile, a short_B may occur in the second light emitting element ED2 of the first light emitting element ED1 and the second light emitting element ED2. As shown in FIG. 15, particles PT may occur on the second anode electrode 122 of the second light emitting element ED2, and a short circuit may occur when the second anode electrode 122 and the cathode electrode 140 of the second light emitting element ED2 are in contact with each other. For this reason, a second current path CP2 in which the second anode electrode 122 and the cathode electrode 140 of the second light emitting element ED2 are directly connected to each other without passing through the second light emitting element ED2 may occur as shown in FIG. 16. Since the resistance in the area where the second anode electrode 122 and the cathode electrode 140 of the second light emitting element ED2 are short-circuited is much smaller than the internal resistance of the second light emitting element ED2, a large amount of current may flow. Therefore, as shown in FIG. 17, when a defect occurs in the second light emitting element ED2 (short_B), the voltage charged in the reference line REFL (reference voltage or initialization voltage) may be discharged at a faster speed than when the first and second light emitting elements ED1 and ED2 are normal (no short).

When the voltage sensed through the AD converter ADC is smaller than the reference value, the defect detection unit 300 may determine that one of the first light emitting element ED1 and the second light emitting element ED2, which are included in the corresponding subpixel, is a defective element.

In the display panel 110 according to one exemplary embodiment of the present disclosure, the position of the first light emitting element ED1 and the second light emitting element ED2, in which the defect occurs, may be determined using the resistance difference between the first anode connection line CL1 and the second anode connection line CL2. In the display panel 110 according to one exemplary embodiment of the present disclosure, the first anode connection line CL1 connected to the first anode electrode 121 may have resistance higher than that of the second anode connection line CL2 connected to the second anode electrode 122.

When a defect occurs in the first light emitting element ED1 (short_A), since the first anode connection line CL1 having relatively high resistance is provided on the current path, as shown in FIG. 17, the discharge speed may be slower than that of the case where a defect occurs in the second light emitting element ED2 (short_A). Therefore, when a defect occurs in the first light emitting element ED1 (short_A), the voltage sensed through the AD converter ADC may be higher than that of the case that a defect occurs in the second light emitting element ED2 (short_B).

When the voltage sensed through the AD converter ADC is lower than a first reference value, the defect detection unit 300 may determine the second light emitting element ED2 as a defective element. In the display panel 110 according to one exemplary embodiment of the present disclosure, a laser cutting area CA2 may be provided in the second anode connection line CL2 connecting the second anode electrode 122 to the driving transistor DT. The second anode connection line CL2 may be provided with the laser cutting area CA2 in an area that does not overlap the first anode connection line CL1. In the display panel 110 according to one exemplary embodiment of the present disclosure, when the second light emitting element ED2 is determined as a defective element, the laser cutting area CA2 of the second anode connection line CL2 may be subjected to laser cutting so as to electrically separate the defective second light emitting element ED2 from the driving transistor DT. As a result, the first light emitting element ED1 of the corresponding subpixel may be normally operated.

Meanwhile, when the voltage sensed through the AD converter ADC is equal to or greater than the first reference value and is smaller than a second reference value greater than the first reference value, the defect detection unit 300 may determine the first light emitting element ED1 as a defective element. The display panel 110 according to an exemplary configuration of the present disclosure may include a laser cutting area CA1 in the first anode connection line CL1 connecting the first anode electrode 121 with the driving transistor DT. The first anode connection line CL1 may include a laser cutting area CA1 in an area that does not overlap the second anode connection line CL2. In the display panel 110 according to one exemplary embodiment of the present disclosure, when the first light emitting element ED1 is determined as a defective element, the laser cutting area CA1 of the first anode connection line CL1 may be subjected to laser cutting so as to electrically separate the defective first light emitting element ED1 from the driving transistor DT. As a result, the second light emitting element ED2 of the corresponding subpixel may be normally operated.

In the display panel 110 according to one exemplary embodiment of the present disclosure, the position of the light emitting element in which a defect occurs may be accurately detected using the resistance difference between the first anode connection line CL1 and the second anode connection line CL2. Furthermore, in the display panel 110 according to one exemplary embodiment of the present disclosure, a product defect rate may be reduced through a repair process. As the product defect rate is reduced, the display panel 110 according to one exemplary embodiment of the present disclosure may reduce a manufacturing process cost and a manufacturing process time, and further reduce a production energy. Also, the present disclosure may reduce occurrence of greenhouse gases that may occur due to a manufacturing process, thereby implementing Environment/Social/Governance (ESG).

Also, in the display panel 110 according to one exemplary embodiment of the present disclosure, the voltage may be sensed through the reference line REFL without using a separate sensing line. When the display panel 110 is a transparent display panel, transmittance may be improved as compared with a structure using a separate sensing line.

Exemplary embodiments of the present disclosure described above are briefly described as follows.

According to exemplary embodiments of the present disclosure, a display device comprises: a driving transistor provided on a substrate; a light emitting element provided on the driving transistor, including an anode electrode, a light emitting layer, and a cathode electrode, the anode electrode including a first anode electrode and a second anode electrode, which are disposed to be spaced apart from each other; a first anode connection line electrically connecting the first anode electrode to the driving transistor; and a second anode connection line electrically connecting the second anode electrode to the driving transistor, wherein the first anode connection line has resistance greater than that of the second anode connection line.

According to exemplary embodiments of the present disclosure, the first anode connection line is provided on a layer different from the second anode connection line.

According to exemplary embodiments of the present disclosure, the first anode connection line is formed of a material different from that of the second anode connection line.

According to exemplary embodiments of the present disclosure, the first anode connection line is made of a silicon-based semiconductor material or an oxide-based semiconductor material.

According to exemplary embodiments of the present disclosure, the second anode connection line is made of an alloy of molybdenum and titanium MoTi.

According to exemplary embodiments of the present disclosure, the driving transistor includes an active layer, a gate electrode, a source electrode, and a drain electrode, the first anode connection line is formed of the same material on the same layer as the active layer of the driving transistor, and the second anode connection line is provided on the driving transistor.

According to exemplary embodiments of the present disclosure, the first anode connection line is electrically connected to one of the source electrode and the drain electrode of the driving transistor at one end, and is electrically connected to the first anode electrode at the other end, and the second anode connection line is electrically connected to one of the source electrode and the drain electrode of the driving transistor at one end, and is electrically connected to the second anode electrode at the other end.

According to exemplary embodiments of the present disclosure, the display device further comprises a metal layer electrically connected to one of the source electrode and the drain electrode of the driving transistor.

According to exemplary embodiments of the present disclosure, the second anode connection line and the metal layer are formed on the same layer with the same material.

According to exemplary embodiments of the present disclosure, the first anode connection line and the second anode connection line at least partially overlap each other.

According to exemplary embodiments of the present disclosure, the first anode connection line includes a first cutting area provided in an area that does not overlap the second anode connection line, and the second anode connection line includes a second cutting area provided in an area that does not overlap the first anode connection line.

According to exemplary embodiments of the present disclosure, the light emitting element includes a first light emitting element including the first anode electrode, the light emitting layer and the cathode electrode, and a second light emitting element including the second anode electrode, the light emitting layer and the cathode electrode, and the first light emitting element and the second light emitting element share the driving transistor.

According to exemplary embodiments of the present disclosure, the display device further comprises: a reference line electrically connected to the first light emitting element and the second light emitting element and to which an initialization voltage is applied during a first period; and an analog-digital AD converter connected to the reference line, and the AD converter is configured to sense a voltage through the reference line within a second period.

According to exemplary embodiments of the present disclosure, the display device further comprises: a first switch connecting a reference voltage source with the reference line during the first period and separating the reference voltage source from the reference line during the second period; and a second switch connecting the AD converter with the reference line during at least a partial period within the second period and separating the AD converter from the reference line during the first period.

According to exemplary embodiments of the present disclosure, the display device further comprises a defect detection unit determining a defective one from the first light emitting element and the second light emitting element based on a voltage sensed through the AD converter.

According to exemplary embodiments of the present disclosure, the defect detection unit determines the second light emitting element as a defective light emitting element when the sensed voltage is lower than the first reference value, and determines the first light emitting element as a defective light emitting element when the sensed voltage is equal to or greater than the first reference value and is smaller than a second reference value which is greater than the first reference value.

According to exemplary embodiments of the present disclosure, a display device comprises: a substrate provided with a plurality of transmissive areas and a plurality of subpixels disposed between the plurality of transmissive areas; a driving transistor provided on the substrate, the driving transistor including an active layer, a gate electrode, a source electrode and a drain electrode; an anode electrode provided in each of the plurality of subpixels, including a first anode electrode and a second anode electrode; a first anode connection line electrically connecting the first anode electrode to the driving transistor; and a second anode connection line electrically connecting the second anode electrode to the driving transistor, wherein the first anode connection line is provided on the same layer as the active layer of the driving transistor.

According to exemplary embodiments of the present disclosure, the second anode connection line is provided on a layer different from the first anode connection line.

According to exemplary embodiments of the present disclosure, the second anode connection line is provided on the driving transistor.

According to exemplary embodiments of the present disclosure, the first anode connection line has resistance greater than that of the second anode connection line.

According to exemplary embodiments of the present disclosure, the first anode connection line is made of a silicon-based semiconductor material or an oxide-based semiconductor material.

According to exemplary embodiments of the present disclosure, the second anode connection line is made of an alloy of molybdenum and titanium MoTi.

According to exemplary embodiments of the present disclosure, the display device further comprises a metal layer electrically connected to one of the source electrode and the drain electrode of the driving transistor.

According to exemplary embodiments of the present disclosure, the second anode connection line and the metal layer are formed on the same layer with the same material.

According to exemplary embodiments of the present disclosure, the first anode electrode includes a first protrusion protruded from one side toward the transmissive area, the second anode electrode includes a second protrusion protruded from one side toward the transmissive area, and the first anode connection line and the second anode connection line are disposed between the first protrusion and the second protrusion.

According to exemplary embodiments of the present disclosure, the display device further comprises: a reference line extended in a first direction between the transmissive areas; and an analog-digital (AD) converter connected to the reference line.

According to exemplary embodiments of the present disclosure, the reference line is connected to a reference voltage source to charge with a voltage applied from the reference voltage source during a first period, and is separated from the reference voltage source to discharge at least a portion of the voltage during a second period.

According to exemplary embodiments of the present disclosure, the AD converter is connected to the reference line within the second period to sense the voltage charged in the reference line.

According to exemplary embodiments of the present disclosure, a manufacturing method of display device comprising: forming a driving transistor on a substrate; providing a light emitting element over the driving transistor, the driving transistor including an anode electrode, a light emitting layer, and a cathode electrode, the anode electrode including a first anode electrode and a second anode electrode, which are disposed to be spaced apart from each other; providing a first anode connection line electrically connecting the first anode electrode to the driving transistor; and providing a second anode connection line electrically connecting the second anode electrode to the driving transistor, wherein the first anode connection line has resistance greater than that of the second anode connection line.

According to exemplary embodiments of the present disclosure, the first anode connection line is made of a silicon-based semiconductor material or an oxide-based semiconductor material.

According to exemplary embodiments of the present disclosure, the second anode connection line is made of an alloy of molybdenum and titanium MoTi.

According to exemplary embodiments of the present disclosure, the method further comprises: forming a first cutting area in an area of the first anode connection line, that does not overlap the second anode connection line, and forming a second cutting area in an area of the second anode connection line that does not overlap the first anode connection line.

According to the present disclosure, the following advantageous effects may be obtained.

In the present disclosure, the position of the light emitting element in which a defect occurs may be accurately detected using the resistance difference between the first anode connection line and the second anode connection line, and a product defect rate may be reduced through a repair process.

Also, in the present disclosure, as the product defect rate is reduced, the manufacturing process cost may be reduced, the manufacturing process time may be shortened, and further, production energy may be reduced. Also, the present disclosure may reduce occurrence of greenhouse gases that may occur due to a manufacturing process, thereby implementing Environment/Social/Governance (ESG).

It will be apparent to those skilled in the art that the present disclosure described above is not limited by the above-described exemplary embodiments and the accompanying drawings and that various substitutions, modifications and variations may be made in the present disclosure without departing from the spirit or scope of the disclosures.

What is claimed is:

1. A display device comprising:
a driving transistor on a substrate;
a light emitting element on the driving transistor, the light emitting element including an anode electrode, a light emitting layer, and a cathode electrode, the anode electrode including a first anode electrode and a second anode electrode that are spaced apart from each other;
a first anode connection line electrically connecting the first anode electrode to the driving transistor; and
a second anode connection line electrically connecting the second anode electrode to the driving transistor,
wherein the first anode connection line has a resistance that is greater than a resistance of the second anode connection line.

2. The display device of claim 1, wherein the first anode connection line is on a layer that is different from the second anode connection line.

3. The display device of claim 1, wherein the first anode connection line includes a material different from a material of the second anode connection line.

4. The display device of claim 1, wherein the first anode connection line includes a silicon-based semiconductor material or an oxide-based semiconductor material.

5. The display device of claim 1, wherein the second anode connection line includes of an alloy of molybdenum and titanium MoTi.

6. The display device of claim 1, wherein the driving transistor includes an active layer, a gate electrode, a source electrode, and a drain electrode,
wherein the first anode connection line includes a same material and is on a same layer as the active layer of the driving transistor, and the second anode connection line is on the driving transistor.

7. The display device of claim 6, wherein the first anode connection line is electrically connected to one of the source electrode and the drain electrode of the driving transistor at one end, and is electrically connected to the first anode electrode at the other end, and
the second anode connection line is electrically connected to one of the source electrode and the drain electrode of the driving transistor at one end, and is electrically connected to the second anode electrode at the other end.

8. The display device of claim 6, further comprising a metal layer electrically connected to one of the source electrode and the drain electrode of the driving transistor.

9. The display device of claim 8, the second anode connection line and the metal layer are formed on the same layer with the same material.

10. The display device of claim 1, wherein the first anode connection line and the second anode connection line at least partially overlap each other.

11. The display device of claim 1, wherein the first anode connection line includes a first cutting area provided in an area that does not overlap the second anode connection line, and
the second anode connection line includes a second cutting area provided in an area that does not overlap the first anode connection line.

12. The display device of claim 1, wherein the light emitting element includes a first light emitting element including the first anode electrode, the light emitting layer and the cathode electrode, and a second light emitting element including the second anode electrode, the light emitting layer and the cathode electrode, and
the first light emitting element and the second light emitting element share the driving transistor.

13. The display device of claim 12, further comprising:
a reference line electrically connected to the first light emitting element and the second light emitting element and to which an initialization voltage is applied during a first period; and
an analog-digital AD converter connected to the reference line, and the AD converter is configured to sense a voltage through the reference line within a second period.

14. The display device of claim 13, further comprising:
a first switch connecting a reference voltage source with the reference line during the first period and separating the reference voltage source from the reference line during the second period; and
a second switch connecting the AD converter with the reference line during at least a partial period within the second period and separating the AD converter from the reference line during the first period.

15. The display device of claim 13, further comprising a defect detection unit determining a defective one from the first light emitting element and the second light emitting element based on a voltage sensed through the AD converter.

16. The display device of claim 15, wherein the defect detection unit determines the second light emitting element as a defective light emitting element when the sensed voltage is lower than the first reference value, and determines the first light emitting element as a defective light emitting element when the sensed voltage is equal to or greater than the first reference value and is smaller than a second reference value which is greater than the first reference value.

17. A display device comprising:
a substrate provided with a plurality of transmissive areas and a plurality of subpixels disposed between the plurality of transmissive areas;
a driving transistor provided on the substrate, the driving transistor including an active layer, a gate electrode, a source electrode and a drain electrode;
an anode electrode provided in each of the plurality of subpixels, the anode electrode including a first anode electrode and a second anode electrode;
a first anode connection line electrically connecting the first anode electrode to the driving transistor; and
a second anode connection line electrically connecting the second anode electrode to the driving transistor,
wherein the first anode connection line is provided on the same layer as the active layer of the driving transistor.

18. The display device of claim 17, wherein the second anode connection line is provided on a layer different from the first anode connection line.

19. The display device of claim 17, wherein the second anode connection line is provided on the driving transistor.

20. The display device of claim 17, wherein the first anode connection line has resistance greater than that of the second anode connection line.

21. The display device of claim 17, wherein the first anode connection line includes a silicon-based semiconductor material or an oxide-based semiconductor material.

22. The display device of claim 17, wherein the second anode connection line includes an alloy of molybdenum and titanium MoTi.

23. The display device of claim 17, further comprising a metal layer electrically connected to one of the source electrode and the drain electrode of the driving transistor.

24. The display device of claim 23, the second anode connection line and the metal layer are formed on the same layer and includes the same material.

25. The display device of claim 17, wherein the first anode electrode includes a first protrusion protruded from one side toward the transmissive area,
the second anode electrode includes a second protrusion protruded from one side toward the transmissive area, and
the first anode connection line and the second anode connection line are disposed between the first protrusion and the second protrusion.

26. The display device of claim 17, further comprising:
a reference line extended in a first direction between the transmissive areas; and
an analog-digital (AD) converter connected to the reference line.

27. The display device of claim 26, wherein the reference line is connected to a reference voltage source to charge with a voltage applied from the reference voltage source during a first period, and is separated from the reference voltage source to discharge at least a portion of the voltage during a second period.

28. The display device of claim 27, wherein the AD converter is connected to the reference line within the second period to sense the voltage charged in the reference line.

29. A manufacturing method of a display device comprising:
forming a driving transistor on a substrate;
providing a light emitting element over the driving transistor, the driving transistor including an anode electrode, a light emitting layer, and a cathode electrode, the anode electrode including a first anode electrode and a second anode electrode, which are disposed to be spaced apart from each other;
providing a first anode connection line electrically connecting the first anode electrode to the driving transistor; and
providing a second anode connection line electrically connecting the second anode electrode to the driving transistor,
wherein the first anode connection line has resistance greater than that of the second anode connection line.

30. The manufacturing method of claim 29, wherein the first anode connection line is includes a silicon-based semiconductor material or an oxide-based semiconductor material.

31. The manufacturing method of claim 29, wherein the second anode connection line is includes an alloy of molybdenum and titanium MoTi.

32. The manufacturing method of claim 29, further comprising:
forming a first cutting area in an area of the first anode connection line, that does not overlap the second anode connection line, and
forming a second cutting area in an area of the second anode connection line that does not overlap the first anode connection line.
